(19) United States
(12) Patent Application Publication
(10) Pub. No.: US 2025/0361140 A1
(43) Pub. Date: Nov. 27, 2025

(54) MICRO-ELECTROMECHANICAL SYSTEMS (MEMS) AND METHODS OF FABRICATING THE SAME

(71) Applicant: Taiwan Semiconductor Manufacturing Company, Ltd., Hsinchu (TW)

(72) Inventor: Yu-Hsun Li, Hsinchu (TW)

(73) Assignee: Taiwan Semiconductor Manufacturing Company, Ltd., Hsinchu (TW)

(21) Appl. No.: 18/916,292

(22) Filed: Oct. 15, 2024

Related U.S. Application Data
(60) Provisional application No. 63/650,068, filed on May 21, 2024.

(51) Int. Cl. B81B 7/00; B81C 1/00

(52) U.S. Cl. CPC B81B 7/0016; B81C 1/00825; B81B 2201/033; B81B 2203/0136; B81B 2203/0163; B81B 2203/0315; B81C 2201/0104; B81C 2201/013; B81C 2201/016; B81C 2201/0176

(57) ABSTRACT

An actuator of a micro-electromechanical system (MEMS) includes a semiconductor substrate. The actuator includes an array of micromechanical arms disposed over the semiconductor substrate. The actuator includes a first capping member disposed over the micromechanical arms. The actuator includes a second capping member disposed opposite the first capping member such that the micromechanical arms extend between the first capping member and the second capping member along a vertical direction.

### CROSS-REFERENCE TO RELATED APPLICATION

This application claims priority to U.S. Provisional Application No. 63/650,068, filed May 21, 2024, the entire disclosure of which is incorporated herein for all purposes.

### BACKGROUND

Micro-electromechanical systems (“MEMS”) include mechanical and electrical features formed by one or more semiconductor manufacturing processes. Examples of MEMS devices include micro-sensors, which convert mechanical signals into electrical signals; micro-actuators, which convert electrical signals into mechanical signals; and motion sensors. For many applications, MEMS devices are electrically connected to application-specific integrated circuits (ASICs), and to external circuitry. While methods of fabricating MEMS have generally adequate, they are not entirely satisfactory in all aspects. For example, impact arising from oscillations of the MEMS during device operation can cause breakage of components of the MEMS. In many instances, such failure may be difficult, if not infeasible, to repair without completely replacing the entire MEMS. Therefore, improvement is desired in fabricating more reliable and impact-resistant MEMS devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a cross-sectional view of an example MEMS including an actuator having an array of micromechanical arms, in accordance with some embodiments.

FIG. 2A is a schematic diagram illustrating a cross-sectional view of an embodiment of an actuator region of the MEMS as shown in FIG. 1, in accordance with some embodiments.

FIG. 2B is a schematic diagram illustrating a cross-sectional view of an embodiment of an actuator region of an actuator region of the MEMS as shown in FIG. 1, in accordance with some embodiments.

FIG. 2C is a schematic diagram illustrating a cross-sectional view of an embodiment of an actuator region of an actuator region of the MEMS as shown in FIG. 1, in accordance with some embodiments.

FIG. 2D is a schematic diagram illustrating a cross-sectional view of an embodiment of an actuator region of an actuator region of the MEMS as shown in FIG. 1, in accordance with some embodiments.

FIG. 3 is a schematic diagram illustrating a top view of a portion of FIG. 1 taken along a plane A-A′ as shown in FIG. 1, in accordance with some embodiment.

FIGS. 4A, 4B, and 4C collectively show a flow diagram of an example method of forming a MEMS, in accordance with some embodiment.

FIGS. 5, 6, 7, 8, 9-1, 9-2, 10, 11, 12, 13, 14, 15, 16, 17, 18, 19, 20, 21, 22-1, 22-2, 23, 24, 25, 26, and 27 are schematic diagrams illustrating cross-sectional views of an example MEMS at intermediate stages of the method as shown in FIGS. 4A, 4B, and 4C, in accordance with some embodiments.

FIG. 28 is a schematic diagram illustrating a perspective view of an example sensor-shift optical image stabilization (OIS) system including a MEMS, in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further still, the terms “about” and “substantially” can indicate a value of a given quantity that varies within 5% of the value (e.g., +1%, +2%, +3%, +4%, +5% of the value).

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

Optical image stabilization (OIS) is a family of techniques that reduce blurring associated with the motion of a camera or other imaging devices during exposure. Image stabilization is typically used in high-end image-stabilized binoculars, still and video cameras, astronomical telescopes, and high-end smartphones. Lens-based OIS operates by moving the lens to compensate for the change in the optical path. Sensor-shift OIS, on the other hand, works by moving the image sensor instead of the lens to compensate for the change in the optical path.

The advantage of moving the image sensor, instead of the lens, is that the image can be stabilized even on lenses made without stabilization. This may allow the stabilization to work with many otherwise-unstabilized lenses. It also reduces the weight and complexity of the lenses. Further, when sensor-shift OIS technology improves, it requires replacing only the camera to take advantage of the improvements, which is typically far less expensive than replacing all existing lenses if relying on lens-based image stabilization.

In some embodiments, sensor-shift OIS is based on a MEMS actuator which can move in, for example, five axes (i.e., X, Y, Roll, Yaw, and Pitch). An image sensor is attached to the MEMS actuator and thus can move in five axes accordingly. In some embodiments, a MEMS actuator includes at least one array of micromechanical arms. The micromechanical arms are each elongated in a first direction and spaced from one another in a second direction perpendicular to the first direction.

However, oscillatory impact on the MEMS actuator can cause breakage of the micromechanical arms. In many instances, it may not be feasible or practical to repair or replace the broken micromechanical arms, given that the critical dimensions of the micromechanical arms being on the microscale or even the nanoscale. As a result, the functioning of the sensor-shift OIS may be significantly compromised. Thus, improvement in the robustness and impact-resistance of micromechanical arms are desirable.

The present disclosure provides techniques to address the above-mentioned challenges. In accordance with some aspects of the disclosure, a MEMS actuator is provided. In some embodiments, the MEMS actuator includes an array of micromechanical arms disposed over a semiconductor substrate. The MEMS actuator includes a first capping member disposed over the micromechanical arms and a second capping member disposed opposite the first capping member. In this regard, the micromechanical arms extend between the first capping member and the second capping member along a vertical direction.

Embodiments of the present disclosure relate generally to micro-electromechanical systems (MEMS) or nano-electromechnical systems (NEMS) devices, and more particularly to an actuator of a MEMS.

According to some embodiments, the MEMS actuator includes a plurality of micromechanical arms, a top capping member (also referred to as “top metal cap” or “top metal connection structure”), and a bottom capping member (also referred to as “bottom metal cap” or “bottom metal connection structure”). The top capping member is physically (i.e., directly) coupled to top portions of a first array of the micromechanical arms (i.e., first micromechanical arms). The bottom capping member is physically (i.e., directly) coupled to bottom portions of the first micromechanical arms. In this regard, the bottom capping member is disposed opposite to the top capping member along a vertical direction.

According to some embodiments, the top capping member includes first rivet structures that protrude into the first micromechanical arms. The bottom capping member includes second rivet structures that protrude into the first micromechanical arms. In this regard, the first rivet structures extend towards the second rivet structures along the vertical direction. In some embodiments, each pair of the first rivet structure and the second rivet structure physically contact one another such that each pair of the first rivet structure and the second rivet structure contact along an interface. In some embodiments, each pair of the first rivet structures and the second rivet structures are physically separated from one another such that a portion of the first micromechanical arms is interposed between the pair of the first rivet structure and the second rivet structure along the vertical direction. In various embodiments, the first rivet structures are configured to anchor a portion of the top capping member to the top portions of the first micromechanical arms, and the bottom capping member are configured to anchor a portion of the bottom capping member to the bottom portions of the first micromechanical arms.

Without limiting the scope of the present disclosure, the top capping member and the bottom capping member advantageously provide vibration isolation, resonance control, as well as damping and energy dissipation for the MEMS actuator. Specifically, the top capping structure provides vibration resistance/isolation for the MEMS actuator by physically tethering at least some of the micromechanical arms (e.g., the first array of micromechanical arms) together along a top surface of the MEMS actuator. Likewise, the bottom capping structure provides vibration resistance/isolation for the MEMS actuator by physically tethering the same micromechanical arms (e.g., the first array of micromechanical arms) together along a bottom surface of the MEMS actuator. In some embodiments, an oscillating micromechanical arm (e.g., a second array micromechanical arms interposed between the first array of micromechanical arms), is interposed between two micromechanical arms tethered together by the top capping member and the bottom capping member.

When external vibrations or disturbances occur during operation of the MEMS actuator, the top capping member and the bottom capping member, each optionally including the rivet structure, may alleviate the impact of vibrations on the motion (e.g., vertical motion) of the micromechanical arms. In some embodiments, the stability provided by the top capping member and the bottom capping member may reduce or minimize unwanted oscillations experienced by the micromechanical arms during operation of the MEMS actuator.

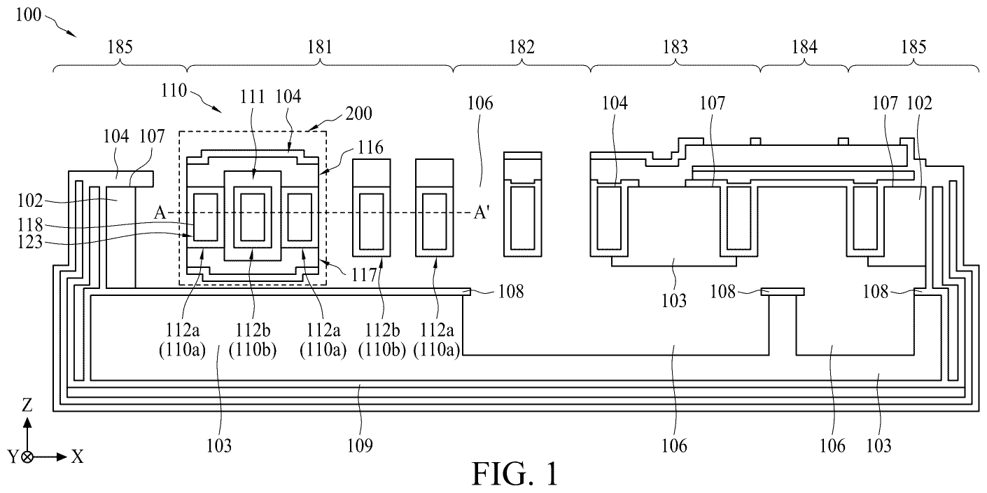

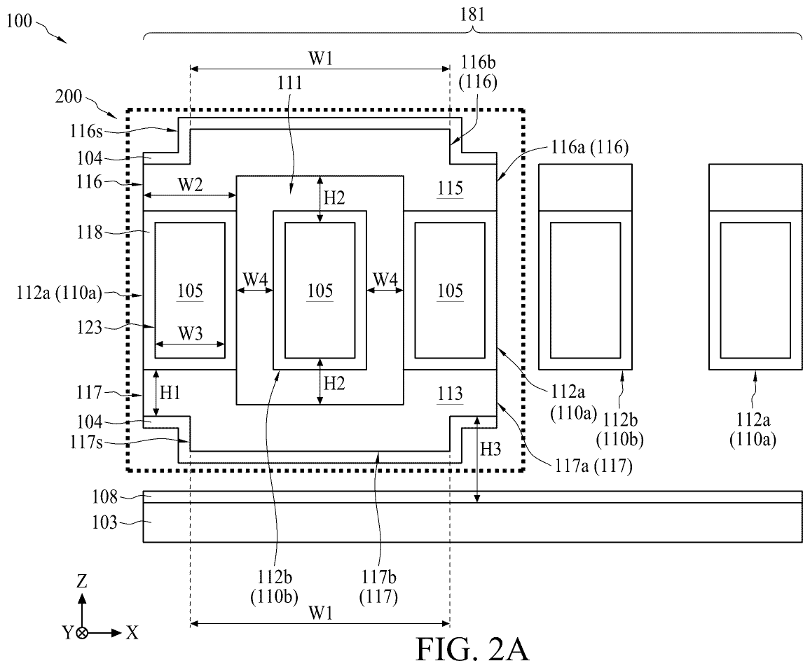

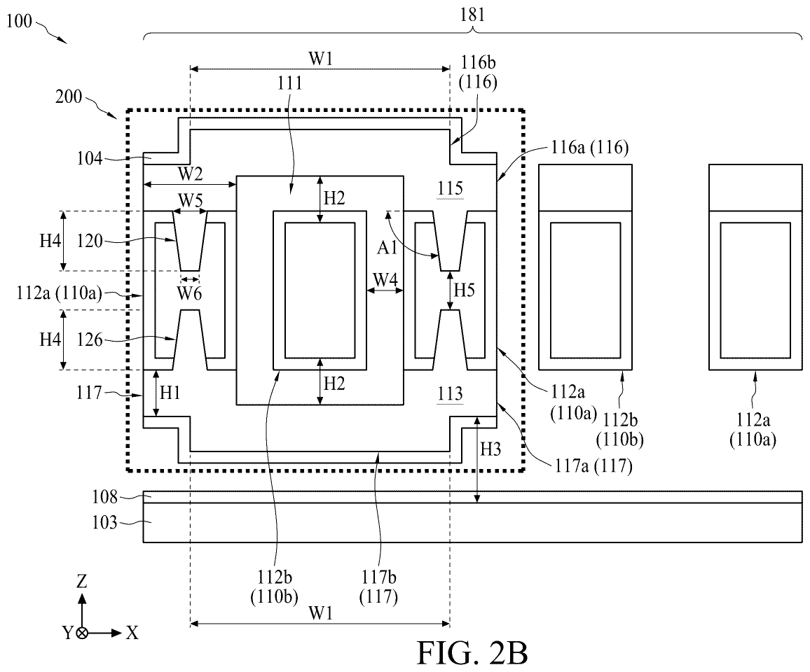

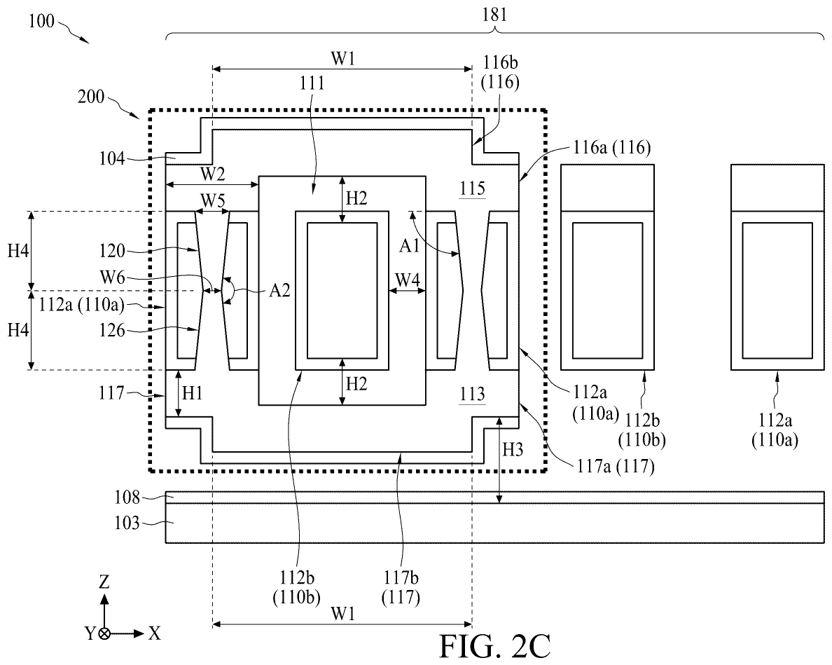

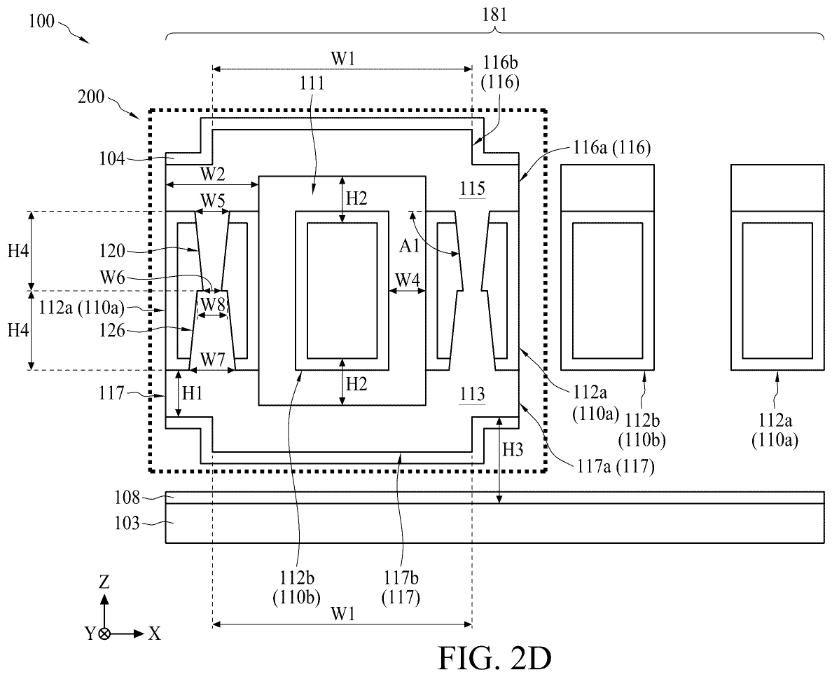

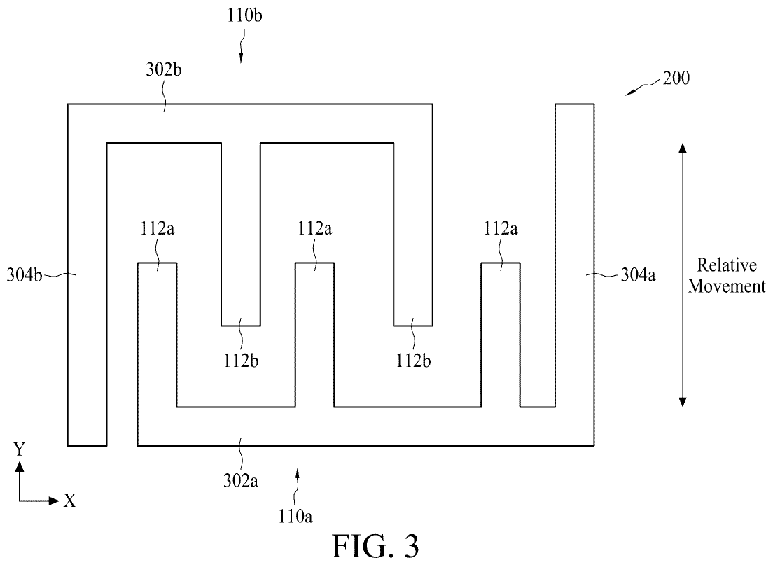

FIG. 1 is a schematic diagram illustrating a cross-sectional view of an example micro-electromechanical system (MEMS) 100 including at least one MEMS actuator 200 in accordance with some embodiments. Though not depicted, in some embodiments, the MEMS 100 may include more than one MEMS actuator 200. FIGS. 2A, 2B, 2C, and 2D are each a schematic diagram illustrating an exploded cross-sectional view of an embodiment of the MEMS actuator 200, in accordance with some embodiments. FIG. 3 is a schematic top view of a portion of the MEMS actuator 200 taken along a plane A-A′ of FIG. 1, in accordance with some embodiments.

In the depicted embodiments, the MEMS 100 includes, among other components, a top wafer 102 (also referred to as a “device wafer”) and a bottom wafer 103 (also referred to as a “handle wafer”) bonded to a backside of the top wafer 102. The MEMS 100 includes a cavity 106 disposed in the top wafer 102. The MEMS 100 further includes a passivation layer 104 (also referred to as “dielectric layer”) disposed over components on a frontside of the top wafer 102, where the MEMS actuator 200 is disposed in (or over) the top wafer 102. In some embodiments, the MEMS actuator 110 includes a first micromechanical arm array 110a, a second micromechanical arm array 110b, a top capping member 116 (also referred to as a “first capping member”), and a bottom capping member 117 (also referred to as a “second capping member”). Additional components may be included in the MEMS 100.

As shown in FIG. 1, the top wafer 102 extends downwardly along a vertical direction (e.g., the Z axis) from a top surface 107 to a bonding layer 108 (also referred to as a bonding interface), the bottom wafer 103 extends upwardly along the vertical direction from a bottom surface 109 to the bonding layer 108. The top wafer 102 and the bottom wafer 103 are bonded by the bonding layer 108. In some embodiments, the bonding layer 108 is a fusion bonding layer. In other words, the top wafer 102 and the bottom wafer 103 are bonded through fusion bonding, such as through a heating and/or pressing process, without the need for adhesives or intermediate layers. In some embodiments, the top wafer 102 has a bonding dielectric layer (not shown) at a backside (i.e., a bottom surface) thereof, and the bottom wafer 103 similarly has a bonding dielectric layer (not shown) at a frontside (i.e., a top surface) thereof, and the backside of the top wafer 102 and the frontside of the bottom wafer 103 are subsequently bonded through fusion of the bonding dielectric layers to form the bonding layer 108.

The top wafer 102 and the bottom wafer 103 may each include a semiconductor material, such as a bulk semiconductor, a semiconductor-on-insulator (SOI) substrate, or the like, which may be doped (e.g., with a p-type or an n-type dopant) or undoped. The semiconductor material in the top wafer 102 and the bottom wafer 103 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In the present embodiments, the top wafer 102 and the bottom wafer 103 each include silicon.

The cavity 106 is interposed between the top surface 107 of the top wafer 102 and the bottom surface 109 of the bottom wafer 103. The cavity 106 defines a continuous space that allows micromechanical arms or other movable microstructures disposed therein to freely move and operate. In some embodiments, a portion of the cavity 106 extends across the bonding layer 108 between the top wafer 102 and the bottom wafer 103. In some embodiments, portions of the cavity 106 are interposed between components of the MEMS 100 along a first horizontal direction (e.g., the X axis).

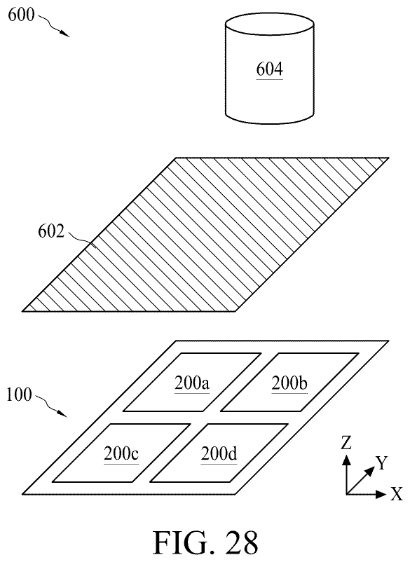

Still referring to FIG. 1, in some embodiments, the MEMS 100 includes multiple sections (or regions) arranged along the first horizontal direction, including a MEMS actuator section 181 (also referred to as a “driving comb section”), a hinge section 182, an inner frame section 183, a spring section 184, and an outer frame section 185. MEMS actuator section 181 includes at least one MEMS actuator 200, which is configured to provide controlled movement or displacement in response to electrical signals. In some embodiments, the MEMS 100 includes more than one MEMS actuator 200. For example, referring to FIG. 28, the MEMS 100 may include MEMS actuator 200a, 200b, 200c, and 200d (collectively referred to as the MEMS actuators 200 as described herein) in the MEMS actuator section 181. The hinge section 182 may include one or more hinges configured to enable pivotal movement of the MEMS actuator 200 or allow for the controlled rotation of other components within the MEMS 100. The inner frame section 183 may provide structural support and stability to the MEMS 100 to maintain the alignment of various components within the MEMS 100. The hinge section 182 may include flexible spring-like structures that provide mechanical support and elasticity to maintain the desired positioning and movement of the components within the MEMS 100 and provide a restoring force to bring the MEMS actuator 200 back to its original position after actuation. The outer frame section 185 is configured to provide structural integrity, protecting the internal components from external and environmental forces.

Referring to FIGS. 1, 2A-2D, and 3 collectively, the first micromechanical arm array 110a and the second micromechanical arm array 110b are disposed within the MEMS actuator section 181 and substantially disposed within the top wafer 102. The first micromechanical arm array 110a includes, among other components, multiple first micromechanical arms 112a. The first micromechanical arms 112a each extend in parallel along a second horizontal direction (i.e., the Y-axis) and are spaced from one another along the first horizontal direction. As shown in detail in FIGS. 2A-2D, top portions of the first micromechanical arms 112a are tethered or coupled to the top capping member 116, and bottom portions of the first micromechanical arms 112a are tethered to the bottom capping member 117. In this regard, the first micromechanical arms 112a extend along the vertical direction between the top capping member 116 and the bottom capping member 117, thereby physically coupling them together. In various embodiments, the second micromechanical arms 112b are not tethered to either the top capping member 116 or the bottom capping member 117 as shown in FIGS. 1-3, allowing them the freedom to vibrate or oscillate in the cavity 106 along the vertical direction between the top capping member 116 and along the first horizontal direction between two neighboring first micromechanical arms 112a.

Likewise, the second micromechanical arm array 110b includes, among other components, multiple micromechanical arms 112b. The second micromechanical arms 112b are spaced from each other in the first horizontal direction. The second micromechanical arms 112b extend in parallel in the second horizontal direction. In some embodiments, although not shown in FIGS. 1-3, rather than having the first micromechanical arms 112a tethered to the top capping member 116 and the bottom capping member 117, the second micromechanical arms 112b are tethered to a set of top capping member and bottom capping member having analogous structures to those of the top capping member 116 and the bottom capping member 117, respectively, while the first micromechanical arms 112a remain untethered. In this regard, each second micromechanical arm 112b extends in the vertical direction between its corresponding top capping member (not shown) and bottom capping member (not shown), thereby physically coupling them together. Similar to the discussion above, such an arrangement allows the untethered first micromechanical arms 112a the freedom to vibrate or oscillate in the cavity 106 along the vertical direction between the top capping member 116 and along the first horizontal direction between two neighboring second micromechanical arms 112b. For purposes of illustration, embodiments of the MEMS 100 described herein include the first micromechanical arms 112a tethered to the top capping member 116 and the bottom capping member 117.

In some embodiments, referring to FIGS. 1-2D collectively, each of the first micromechanical arms 112a and the second micromechanical arms 112b (hereafter collectively referred to as micromechanical arms 112) includes a major body 123 and a first dielectric layer 118 disposed on and surrounding each surface of the major body 123. The first dielectric layer 118 encloses the major body 123 and isolates the major body 123 from the cavity 106 and the top capping member 116. In some embodiments, the first dielectric layer 118 serves as an etch stop layer that protects the major body 123 from being inadvertently etched during a subsequently performed silicon release process. The top capping member 116 extends in the first horizontal direction and connects the top portions of two neighboring first micromechanical arms 112a. Similarly, the bottom capping member 117 extends in the first horizontal direction and connects the bottom portions of the two neighboring first micromechanical arms 112a.

In some embodiments, the major body 123 of each micromechanical arm 112 includes a first silicon layer 105 (also referred to as a “semiconductor layer”) of amorphous silicon. In some embodiments, the major body 123 of each micromechanical arm 112 has the same composition as the top wafer 102 (and/or the bottom wafer 103). In some embodiments, the first dielectric layer 118 includes a dielectric material, such as silicon dioxide (SiO₂). In some embodiments, the top capping member 116 includes a second metal layer 115 and the bottom capping member 117 includes a first metal layer 113. The first metal layer 113 and the second metal layer 115 each include a conductive material (i.e., a metal), such as an aluminum copper alloy (AlCu). In some embodiments, the first metal layer 113 and the second metal layer 115 have the same composition. In some embodiment, the first metal layer 113 and the second metal layer 115 have different compositions.

Other combinations of materials may also be applicable in other embodiments of each of the major body 123, the first dielectric layer 118, the top capping member 116, and the bottom capping member 117. For example, the major body 123 may include single crystal silicon, amorphous silicon, other suitable semiconductor materials, or a combination thereof. The first dielectric layer 118 may include silicon nitride (Si₃N₄), silicon carbide (SiC), a low-k dielectric material (e.g., undoped silicon glass (USG), fluorosilicate glass (FSG), borophosphosilicate glass (BPSG), other suitable low-k dielectric materials) having a dielectric constant less than that of silicon oxide, other suitable dielectric materials, or combinations thereof. Each of the first metal layer 113 (i.e., the bottom capping member 117) and the second metal layer 115 (i.e., the top capping member 116) may include titanium nitride (TiN), tantalum nitride (TaN), Al—Si—Cu alloy, copper (Cu), tungsten (W), ruthenium (Ru), cobalt (Co), other suitable conductive materials, or combinations thereof.

Although two of the first micromechanical arms 112a and one of the second micromechanical arms 112b are illustrated in FIGS. 1-2D, it is not intended to be limiting. For example, in some embodiments, the first micromechanical arm array 110a may include, for example, three, four, five, or eight, of the first micromechanical arms 112a, while the second micromechanical arm array 110b may include, for example, three, four, five, or eight, of the second micromechanical arms 112b. Other arrangements of the micromechanical arms 112 may also be within the scope of the present disclosure.

Referring to FIGS. 1-3 collectively, the first micromechanical arms 112a and the second micromechanical arms 112b are interleaved with and spaced from one another along the first horizontal direction. In the example embodiments shown herein, one of the second micromechanical arms 112b is interposed between two neighboring first micromechanical arms 112a. Furthermore, referring to the cross-sectional views of the MEMS 100 depicted in FIGS. 1-2D, a cavity 111 surrounds surfaces of the second micromechanical arm 112b, thereby separating the second micromechanical arm 112b from the two neighboring first micromechanical arms 112a, the top capping member 116, and the bottom capping member 117. In this regard, the second micromechanical arm 112b is allowed to oscillate in the cavity 111 during the operation of the MEMS 100. With the placement of the top capping member 116 and the bottom capping member 117, the impact arising from at least the vertical oscillation of the second micromechanical arm 112b in the cavity 111 can be alleviated, thereby reducing or preventing inadvertent breakage of the components of the MEMS actuator 200.

As described above, in some embodiments (not depicted herein), the second micromechanical arm array 110b is tethered or coupled its corresponding top capping member and the bottom capping member similar to the top capping member 116 and the bottom capping member 117, respectively, while the first micromechanical arm array 110a remain untethered. The corresponding top capping member and the bottom capping member extend along the first horizontal direction and connects neighboring second micromechanical arms 112b.

Embodiments of the structure of the MEMS actuator 200 are described in further detail below in reference to FIGS. 2A-2D. In some embodiments, referring to FIG. 2A, the top capping member 116 includes a top proximal portion 116a coupled to a top distal portion 116b. The top proximal portion 116a is further coupled or tethered to the top portions of the first micromechanical arms 112a. The top proximal portion 116a and the top distal portion 116b are offset from one another along the vertical direction such that a connecting portion therebetween has a top step profile 116s.

Similarly, the bottom capping member 117 includes a bottom proximal portion 117a coupled to a bottom distal portion 117b. The bottom proximal portion 117a is further coupled or tethered to the bottom portions of the first micromechanical arms 112a. The bottom distal portion 117b faces a frontside of the bottom wafer 103. The bottom proximal portion 117a and the bottom distal portion 117b are offset from one another along the vertical direction such that a connecting portion therebetween has a bottom step profile 117s.

In some embodiments, as depicted in FIG. 2A, the top capping member 116 is disposed entirely above a top surface of the first micromechanical arms 112a. Stated differently, an interface between the top capping member 116 and the first micromechanical arm 112a is formed along the bottom surface of the top capping member 116 (i.e., the top proximal portion 116a) and the top surface of the first micromechanical arm 112a. Analogously, the bottom capping member 117 is disposed entirely below a bottom surface of the first micromechanical arms 112a such that an interface between the bottom capping member 117 and the first micromechanical arm 112a is formed along the top surface of the bottom capping member 117 (i.e., the bottom proximal portion 117a) and the bottom surface of the first micromechanical arm 112a.

In an example embodiment, the top distal portion 116b and the bottom distal portion 117b each have a width W1 extending along the first horizontal direction. The top proximal portion 116a and the bottom proximal portion 117a each have a width W2 extending along the first horizontal direction. The width W2 is less than the width W1. Each of the micromechanical arms 112 has a width W3 and are separated from one another by a distance W4 along the first horizontal direction. In some embodiments, the width W3 is less than the width W2. In some examples, the width W1 is greater than about 4 μm, the width W2 is greater than about 2 μm, the width W3 is greater than about 2 μm, and the distance W4 is greater than about 1 μm. In some embodiments, the width W1 is greater than the width W2, which is greater than the width W3, which is greater than the width W4.

Further to the example embodiments above, the top proximal portion 116a and the bottom proximal portion 117a each have a height H1 extending along the vertical direction. A bottom portion of the second micromechanical arm 112b is separated from the bottom distal portion 117b by a distance H2 along the vertical direction. Similarly, a top portion of the second micromechanical arm 112b is also separated from the top distal portion 116b by the distance H2. In this regard, the distance W4 and the distance H2 collectively define dimensions of the cavity 111 surrounding the second micromechanical arm 112b. The bottom proximal portion 117a is separated from the frontside of the bottom wafer 103 by a distance H3. In some examples, the height H1 is greater than about 2 μm, the distance H2 is greater than about 1 μm, and the distance H3 is greater than about 2 μm. Other dimensions and configurations may also be applicable in other configurations of the MEMS actuator 200.

In some embodiments, referring to FIG. 2B, the top proximal portion 116a of the MEMS actuator 200 includes first rivet structures 120 (also referred to as “first protrusions” or “first protruding portions”) extending into the first micromechanical arms 112a along the vertical direction. In some embodiments, the first rivet structure 120 includes a trapezoid shape having a top width W5, a bottom width W6, and a height H4. In some embodiments, the bottom width W6 is less than the top width W5, where the top width W5 and the bottom width W6 each extend along the first horizontal direction. In some examples, the top width W5 is greater than about 1.5 μm, the bottom width W6 is greater than about 1 μm, and the height H4 is greater than about 4 μm. Furthermore, the first rivet structure 120 includes a pair of slanted sidewalls each disposed at an angle A1 with respect to the top proximal portion 116a. In some embodiments, the angle A1 is an obtuse angle, i.e., greater than about 90° and less than about 180°. In this regard, the slanted sidewalls point towards one another at a distance away from the top proximal portion 116a along the vertical direction.

Similarly, the bottom proximal portion 117a of the MEMS actuator 200 includes second rivet structures 126 (also referred to as “second protrusions” or “second protruding portions”) extending into the first micromechanical arms 112a along the vertical direction. In the embodiment depicted in FIG. 2B, the first rivet structures 120 and the second rivet structure 126 have substantially the same structure and dimension. In other words, the first rivet structures 120 and the second rivet structure 126 are symmetrically structured. In this regard, description of the structure and dimension of the second rivet structure 126 is substantially the same as that of the first rivet structure 120 and is therefore not repeated herein for purposes of brevity.

In some embodiments, still referring to FIG. 2B, each of the first rivet structures 120 and their corresponding second rivet structures 126 are separated by a distance H5 along the vertical direction. In this regard, a portion of the first silicon layer 105 (i.e., the major body 123) is interposed between the first rivet structure 120 and the corresponding second rivet structure 126. In some embodiments, the distance H5 is greater than or equal to the bottom width W6. For example, the distance H5 may be greater than or equal to about 1 μm.

In some embodiments, referring to FIG. 2C, the first rivet structures 120 are physically coupled or connected to their corresponding second rivet structures 126 along the vertical direction. In other words, the first rivet structures 120 and their corresponding second rivet structures 126 are contiguous along the vertical direction and the distance H5 defined in FIG. 2B is substantially zero. In some embodiments, a sidewall of the first rivet structure 120 and a sidewall of the corresponding second rivet structure 126 form an angle A2 that is obtuse, i.e., greater than about 90° and less than about 180°.

In some embodiments, referring to both FIGS. 2B and 2C, the first rivet structures 120 and their corresponding second rivet structures 126 are configured to be substantially symmetric. For example, the first rivet structures 120 and their corresponding second rivet structures 126 may be configured to have substantially the same shape (e.g., a trapezoid) and the same dimensions (e.g., a top length of the second rivet structure 126 is substantially the same as the bottom width W6 of the first rivet structure 120).

In contrast, referring to FIG. 2D, the first rivet structures 120 and their corresponding second rivet structures 126 are configured to be substantially asymmetric in structure. In one example, the first rivet structures 120 and their corresponding second rivet structures 126 may be configured to have substantially the same shape (e.g., a trapezoid) but different dimensions (e.g., different top lengths and the bottom lengths). In another example, the first rivet structures 120 and their corresponding second rivet structures 126 may be configured to have different shapes and different dimensions. FIG. 2D illustrates an embodiment of the former example in which the first rivet structure 120 has the top width W5 and the bottom width W6 as described above, and the second rivet structure 126 has a bottom width W7 and a top width W8, where the bottom width W7 is greater than the top width W5, and the top width W8 is greater than the bottom width W6.

Even though embodiments depicted in FIGS. 2B-2D illustrate both the first rivet structures 120 and their corresponding second rivet structures 126, it is understood that some other embodiments of the present disclosure do not require both the first rivet structures 120 and the second rivet structures 126. In one example, the MEMS actuator 200 does not include the second rivet structures 126 and may include the top capping member 116, the bottom capping member 117, and the first rivet structures 120 extending from the top capping member 116 towards the bottom capping member 117. In another example, the MEMS actuator 200 does not include the first rivet structures 120 and may include the top capping member 116, the bottom capping member 117, and the second rivet structures 126 extending from the bottom capping member 117 towards the top capping member 116.

FIG. 3 is a schematic diagram illustrating the top view of the MEMS actuator 200 taken along the plane A-A′, which extends along the X-Y plane, as shown in FIG. 1, in accordance with some embodiments. The plane A-A′ is interposed between the top capping member 116 and the bottom capping member 117. In this regard, FIG. 3 does not illustrate either the top capping member 116 or the bottom capping member 117.

In the embodiment shown in FIG. 3, the MEMS actuator 200 includes the first micromechanical arm array 110a and the second micromechanical arm array 110b interleaved with one another. The first micromechanical arm array 110a includes the first micromechanical arms 112a extending along the second horizontal direction, a spine beam 302a extending perpendicular to the first micromechanical arms 112a and along the first horizontal direction, and a main beam 304a extending perpendicular to the first micromechanical arms 112a and along the second horizontal direction. Likewise, the second micromechanical arm array 110b includes the second micromechanical arms 112b extending along the second horizontal direction, a spine beam 302b extending along the first horizontal direction, and a main beam 304b extending along the second horizontal direction.

The first micromechanical arms 112a are spaced from one another along the first horizontal direction and extend from the spine beam 302a along the second horizontal direction, forming a first comb structure. Similarly, the second micromechanical arms 112b are spaced from one another along the first horizontal direction and extend from the spine beam 302a along the second horizontal direction, forming a second comb structure.

As described above, the first micromechanical arms 112a (i.e., the first micromechanical arm array 110a) and the second micromechanical arms 112b (i.e., the second micromechanical arm array 110b) are interleaved with and spaced from one another along the first horizontal direction. When a voltage or electrical potential tension is applied between the neighboring micromechanical arms 112a and 112b, the first micromechanical arm array 110a and the second micromechanical arm array 110b are attracted to each other due to an electrostatic force. In some embodiments, the electrostatic force is proportional to the square of the applied voltage. On the other hand, a restoring force that separates the first micromechanical arm array 110a from the second micromechanical arm array 110b may be used to balance the electrostatic force. In some embodiments, the restoring force is provided by a spring structure. As a result, a relative movement (shown by the arrow in FIG. 3) occurs along the second horizontal direction between the first micromechanical arm array 110a and the second micromechanical arm array 110b. In some embodiments, movement in additional directions can be achieved by combining multiple MEMS actuators that are capable of moving in different directions.

In one example, the main beam 304a is fixed with respect to the main body of the MEMS actuator 200, and the main beam 304b moves relative to the main body of the MEMS actuator 200. In another example, the main beam 304b is fixed with respect to the main body of the MEMS actuator 200, and the main beam 304a moves relative to the main body of the MEMS actuator 200. In each of the above two examples, electrical signals are converted into mechanical signals, and the movement of the MEMS actuator 200 is controlled by the electrical signals.

It should be understood that the structures shown in FIG. 3 is not drawn to scale but simplified to illustrate the principle of operation of the example MEMS actuator 200. The MEMS actuator 200 can include other components not depicted or described herein.

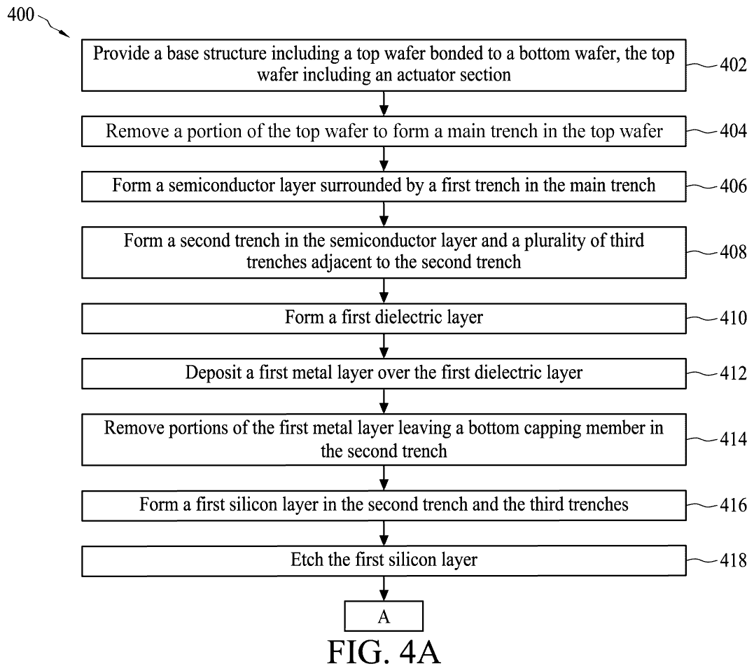

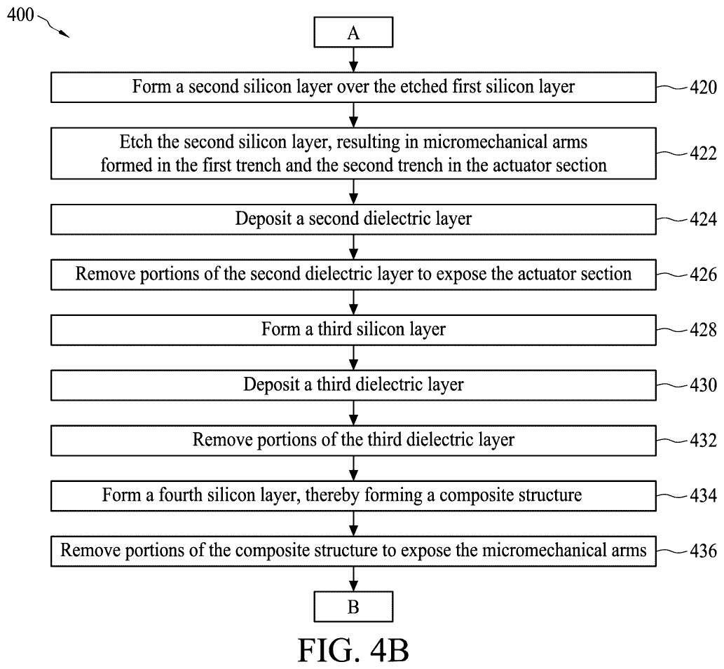

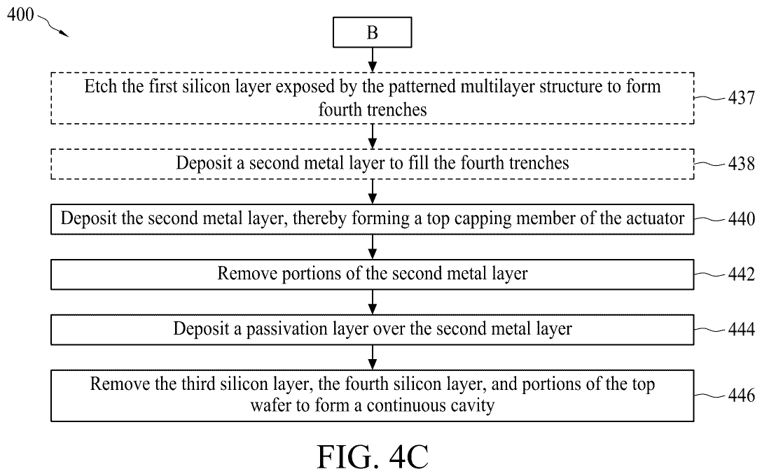

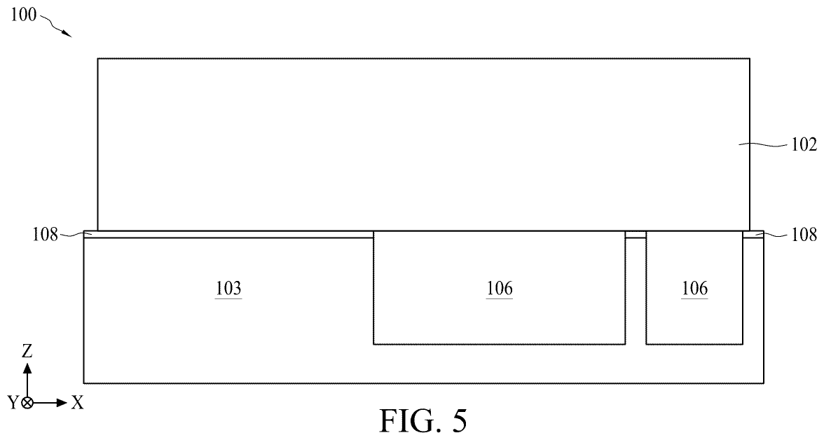

FIGS. 4A, 4B, and 4C collectively show a flowchart of an example method 400 for fabricating an embodiment of the MEMS 100, which includes the MEMS actuator 200 as depicted in one or more of FIGS. 1-3. It is noted that the method 400 is merely an example and is therefore not intended to limit the present disclosure. Accordingly, additional operations may be provided before, during, and after the method 400 of FIGS. 4A-4C. In some embodiments, operations of the method 400 may be described with reference to cross-sectional views of the MEMS 100 at intermediate stages of the method 400 as shown in FIGS. 5-27, which will be discussed in further detail below.

At operation 402, referring to FIG. 5, a base structure of the MEMS 100 is provided. The base structure includes the top wafer 102 and the bottom wafer 103 bonded at the bonding layer 108. The top wafer 102 may be bonded to the bottom wafer 103 by any suitable process, such as a fusion bonding process. In some embodiments, the top wafer 102 is bonded to the bottom wafer 103 after processing one or both of the top wafer 102 and the bottom wafer 103. For example, the bottom wafer 103 may be patterned by a photolithography process, for example, to form the cavities 106.

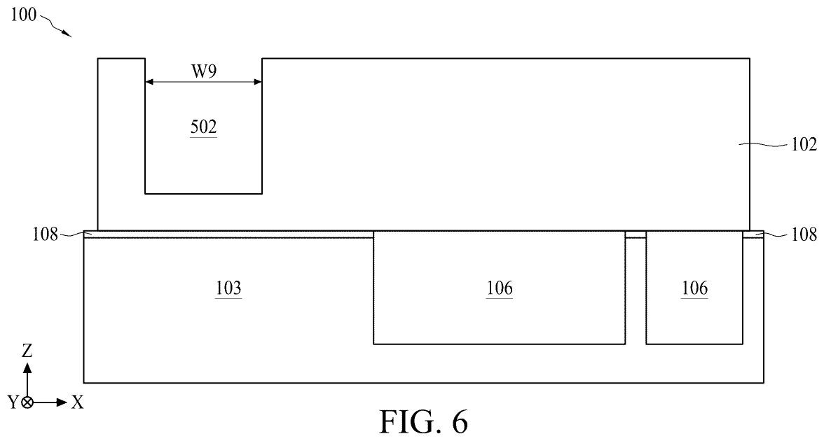

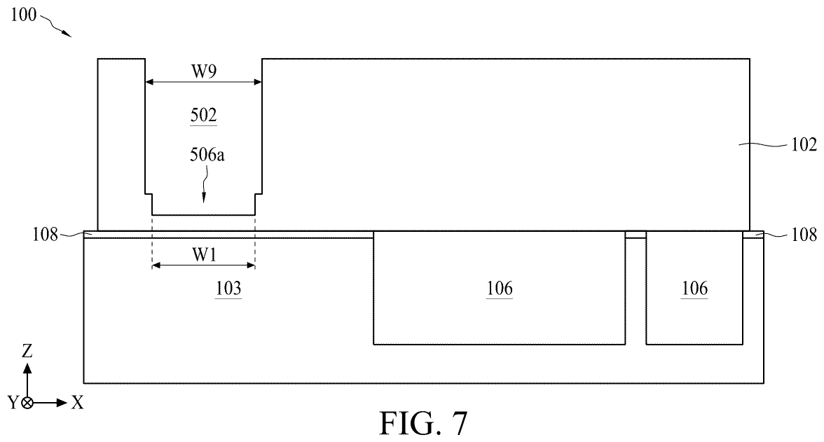

At operations 404-408, referring to FIGS. 6-12 collectively, a first trench 506, a second trench 507, and a plurality of third trenches 508a, 508b, 508c, 508d, 508e, and 508f (collectively referred to as third trenches 508) are formed in the top wafer 102. The first trench 506, the second trench 507, and the third trenches 508 separated from one another along the first horizontal direction by portions of the top wafer 102.

Generally, various trenches in the top wafer 102 are formed photolithography techniques. For example, photolithography techniques utilize a photoresist material (not shown) that is deposited, irradiated (exposed), and developed to remove a portion of the photoresist material. The remaining patterned photoresist material, hereafter referred to as a photomask, protects the underlying material, such as portions of the top wafer 102 outside the trenches to be formed, from subsequent processing steps, such as an etching process. For example, the photomask is used to etch the top wafer 102 by a suitable etching process, such as a dry etching process, a wet etching process, other suitable processes, or combinations thereof. After patterning the top wafer 102, the photomask is removed by a suitable process, such as plasma ashing or resist stripping.

For example, at operation 404, referring to FIG. 6, a main trench 502 is first formed in the MEMS actuator section 181 in the top wafer 102 by a first patterning process using a first photomask (not shown). In some embodiments, the main trench 502 has a width W9 extending along the first horizontal direction. The width W9 defines an overall width of the MEMS actuator 200.

Referring to FIG. 7, the main trench 502 is further patterned to form a horizontal portion 506a of the first trench 506 by a second patterning process using a second photomask (not shown). The horizontal portion 506a defines a space in which the bottom distal portion 117b is formed and is thus formed to have the width W1 as described in detail above.

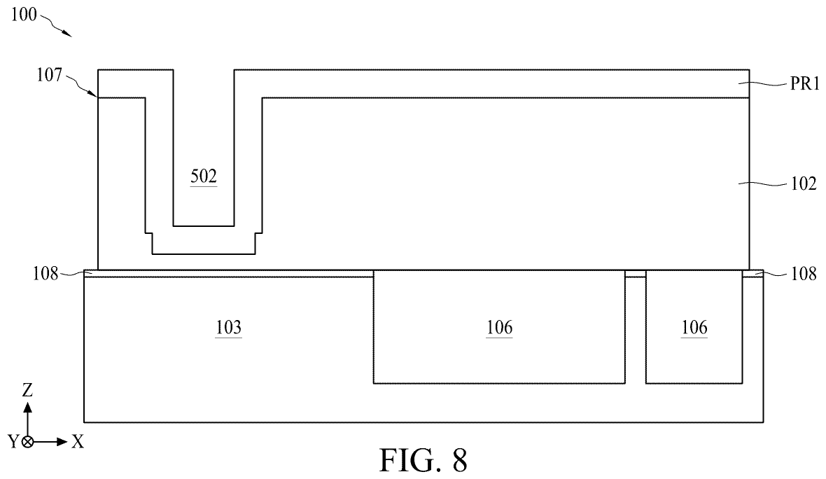

At operation 406, referring to FIGS. 8-10, a semiconductor layer 504 is formed in the main trench 502, where the semiconductor layer 504 is surrounded by the first trench 506. In some embodiments, the semiconductor layer 504 includes polycrystalline silicon (hereafter referred to as “polysilicon”) and may therefore be alternatively referred to as a “silicon layer.” Referring to FIG. 8, a photomask PR1 is formed to partially fill the main trench 502 and overlay the top surface 107. The photomask PR1 includes a photoresist material described in detail above. The photomask PR1 may be formed by first depositing a blanket layer of the photoresist material over the top wafer 102, thereby completely filling the main trench 502. Then, the photoresist material is patterned to form the photomask PR1, which defines a space in which the semiconductor layer 504 is subsequently formed.

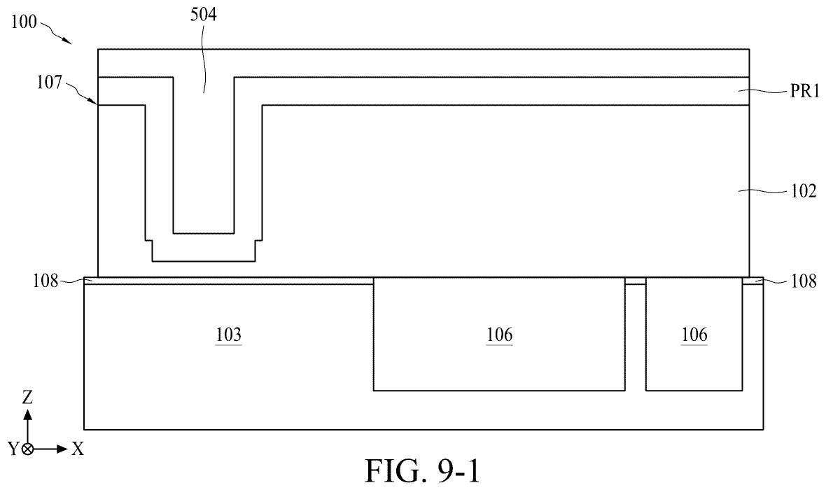

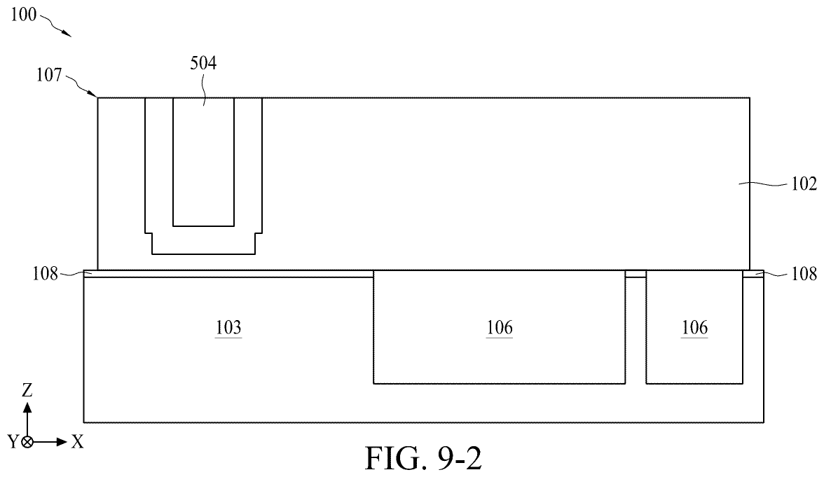

Referring to FIG. 9-1, the semiconductor layer 504 is formed over the photomask PR1 to completely fill the main trench 502. In some embodiments, the semiconductor layer 504 has a composition that is substantially the same as the top wafer 102 and the bottom wafer 103. As depicted herein, a top portion of the semiconductor layer 504 is formed on a top surface of the photomask PR1. Referring to FIG. 9-2, the semiconductor layer 504 is subsequently planarized using a suitable process, such as a chemical-mechanical polishing (CMP) process. In some embodiments, planarizing the semiconductor layer 504 also removes a top portion of the photomask PR1 from a top surface of the top wafer 102.

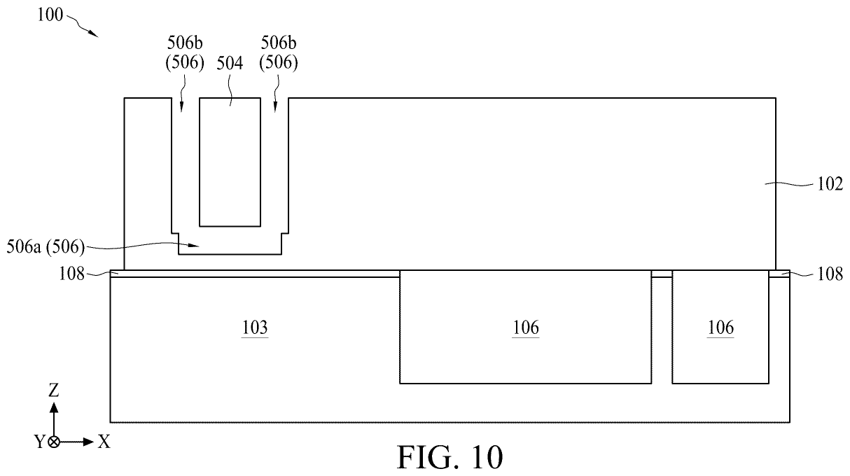

Subsequently, referring to FIG. 10, the photomask PR1 is removed from the top wafer 102 to form the first trench 506, which includes the horizontal portion 506a coupled to two vertical portions 506b. The horizontal portion 506a extends along the first horizontal direction, and each of the two vertical portions 506b extends along the vertical direction. As described above, the horizontal portion 506a defines the space in which the bottom distal portion 117b is subsequently formed. The photomask PR1 may be removed by any suitable method, such as plasma ashing or resist stripping.

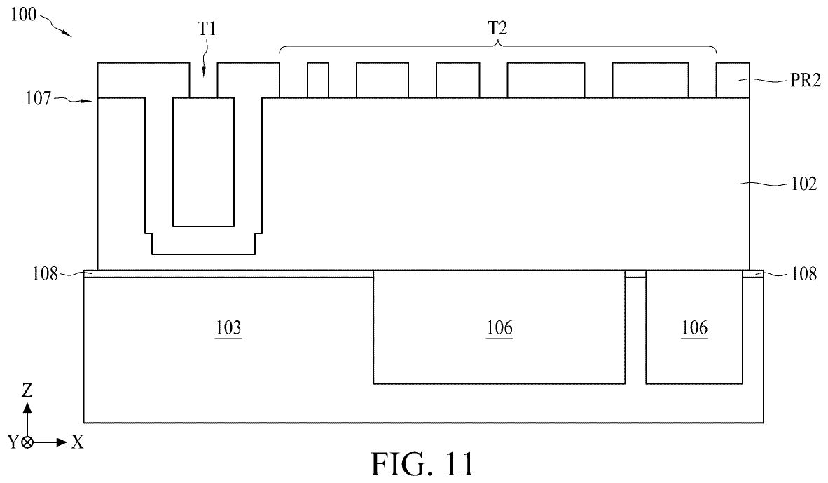

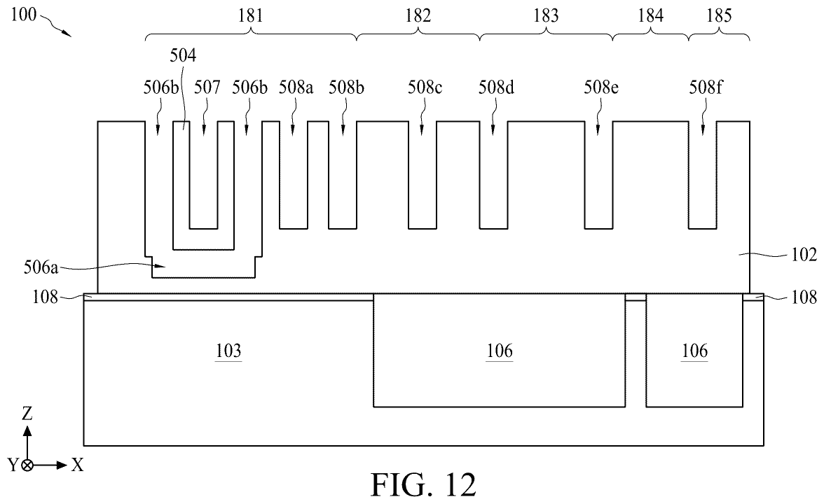

At operation 408, referring to FIGS. 11 and 12, the second trench 507 and the third trenches 508 are formed in the semiconductor layer 504 and the top wafer 102, respectively. Referring to FIG. 11, a photomask PR2 is formed over the top wafer 102 to fill the first trench 506 and overlay the top surface 107. The photomask PR2 defines a plurality of trenches, including a trench T1 that exposes a portion of the semiconductor layer 504 and a plurality of trenches T2 that expose portions of the top wafer 102 adjacent to the trench T1. The photomask PR2 may be similar to the photomask PR1 in composition and patterned in a process similar to that described above.

Referring to FIG. 12, the semiconductor layer 504 and the top wafer 102 are etched using the photomask PR2 as a mask, resulting in the second trench 507 and the third trenches 508 each extending along the vertical direction, respectively. The second trench 507 extends partially through the semiconductor layer 504 such that it is surrounded by portions of the semiconductor layer 504. In some embodiments, the second trench 507 and the third trenches 508 are formed to substantially the same depth. In the depicted embodiment, the first trench 506, the second trench 507, and the third trenches 508a and 508b are formed in the MEMS actuator section 181; the third trenches 508c is formed in the hinge section 182; the third trenches 508d and 508e are formed in the inner frame section 183; and the third trench 508f is formed in the outer frame section 185.

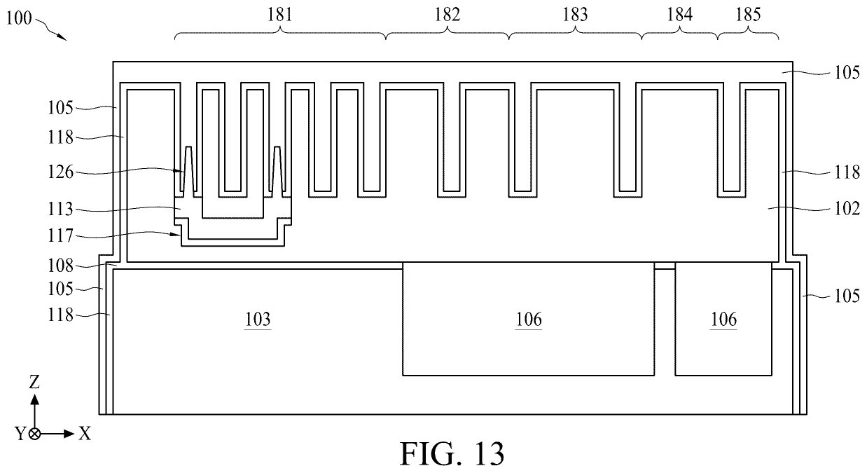

At operation 410, referring to FIG. 13, the first dielectric layer 118 is formed conformally over the various sections of the MEMS 100. In some embodiments, the first dielectric layer 118 is formed along bottom and sidewall surfaces of the first trench 506, the top and sidewall surfaces of the top wafer 102. In some embodiments, the first dielectric layer 118 includes an oxide (e.g., silicon oxide) and is formed by an oxidation process, such as a thermal oxidation process. The thermal oxidation process may be implemented by placing the base structure (i.e., the top wafer 102 bonded to the bottom wafer 103) in a thermal tube (e.g., a high-temperature furnace or oxidation furnace), and purging the thermal tube with an inert gas, such as nitrogen (N₂), to create an oxygen-free atmosphere. The thermal tube is then heated to the desired temperature (e.g., from 800° C. to 1600° C.). Once the desired temperature is reached, oxygen or an oxygen-containing gas, such as dry air or pure oxygen, is introduced into the thermal tube. The oxygen reacts with the exposed silicon surfaces in the first trench 506, the second trench 507, and the third trenches 508, leading to the formation of a thermal silicon oxide layer as the first dielectric layer 118. The reaction proceeds until a desired thickness of the first dielectric layer 118 is achieved. Other oxidation processes, such as a chemical oxidation process, may also be used to form the first dielectric layer 118.

At operation 412, referring to FIG. 13, the first metal layer 113 is deposited over the first dielectric layer 118. In some embodiments, the first metal layer 113 completely fills each of the first trench 506, the second trench 507, and the third trenches at operation 412. The first metal layer 113 may be formed by any suitable method such as physical vapor deposition (PVD), chemical vapor deposition (CVD), electroplating, electroless plating, sputtering deposition, other suitable methods, or combinations thereof. In some embodiments, the first metal layer 113 includes an aluminum copper alloy (AlCu). For example, the first metal layer 113 containing AlCu may be formed by a sputtering deposition process, which includes bombarding a first garget substrate of Al and a second target substrate of Cu with high-energy ions, and sputtering or co-depositing ejected Al and Cu atoms from their respective target substrate on the base structure to form the first metal layer 113. An annealing or other post-sputtering treatment process may be subsequently be performed. Similarly, an electroplating process may be performed to form a metal layer of Al and Cu on the base structure by placing the base structure in an electroplating bath containing Al ions and Cu ions, applying an electric current to initiate the reduction of the Al ions and Cu ions and co-deposit Al and Cu on the base structure. In some embodiments, a planarization process (e.g., a CMP process) is performed to planarize the first metal layer 113.

At operation 414, still referring to FIG. 13, the first metal layer is etched to form at least the bottom capping member 117 in a bottom portion of the first trench 506, including at least the horizontal portion 506a. In some embodiments, a photomask (not shown) is applied over the first metal layer 113, and the first metal layer 113 is etched such that portions of the first metal layer 113 are completely removed from the second trench 507 and the third trenches 508, leaving portions of the first metal layer 113 in the bottom portion of the first trench 506. In some embodiments, a dry etching process is implemented to etch the first metal layer 113. Examples of the dry etching process include but are not limited to reactive ion etching (RIE), deep reactive ion etching (DRIE), plasma etching, ion beam etching (IBE), inductively coupled plasma (ICP) etching, or other suitable techniques. One or more non-liquid or gas etchants may be used in the dry etching process. Example enchants for etching the first metal layer 113 include but are not limited to a chlorine-containing etchant (e.g., chlorine (Cl₂), boron trichloride (BCl₃), chlorine trifluoride (ClF₃), etc.), a mixture of oxygen (O₂) and carbon tetrafluoride (CF₄), other suitable etchants, or combinations thereof.

In some embodiments, as depicted in FIG. 13, parameters of the dry etching process are controlled such that the first metal layer 113 is etched to include the second rivet structures 126 protruding from the bottom capping member 117 along the vertical direction, as depicted in FIGS. 2B-2D. In some embodiments, parameters of the dry etching process are controlled such that a top surface of the bottom capping member 117 is etched to be substantially planar, as depicted in FIGS. 1 and 2A. After etching the first metal layer 113 to form the bottom capping member 117, the photomask is removed from the base structure by a suitable process, such as resist stripping or plasma ashing.

At operation 416, still referring to FIG. 13, the first silicon layer 105 is formed over the etched first metal layer 113, thereby completely filling the first trench 506, the second trench 507, and the third trenches 508. As depicted herein, portions of the first silicon layer 105 are formed over a top surface of the first dielectric layer 118.

As described above, the first silicon layer 105 includes polysilicon. The first silicon layer 105 may be formed by any suitable method, such as thermal deposition, CVD, atomic layer deposition (ALD), other suitable methods, or combinations thereof. In one example, a silicon-containing gas such as silane (SiH₄) or SiH₂Cl₂ may be used as a precursor to form the first silicon layer 105 on the base structure placed in a thermal tube at high temperature. In another example, an ALD process may be performed to form the first silicon layer 105 on the base structure.

In yet another example, the first silicon layer 105 may be formed by performing a two-step process. The two-step process may include first depositing a seed layer (not shown separately) using a CVD technique and subsequently growing a layer of polysilicon on the seed layer using a thermal deposition technique. In the first step, a thin seed layer of silicon is deposited onto a substrate surface (e.g., the etched first metal layer 113) through the CVD process. For example, a precursor gas, such as silane (SiH₄), may be introduced into a reaction chamber where it decomposes in the presence of a catalyst or high-energy plasma, to deposit a thin seed layer of silicon atoms onto the exposed first dielectric layer 118. The seed layer may act as a nucleation site for the subsequent growth of polysilicon thereover. In the second step, a thermal deposition technique, such as thermal evaporation, is performed to grow a thicker silicon layer on top of the seed layer. A high-temperature environment (e.g., 800 to 1,600° C.) may be used to evaporate silicon atoms from a source material. The thicker silicon layer is then formed on the thin seed layer of silicon atoms formed in the first step, resulting in the first silicon layer 105.

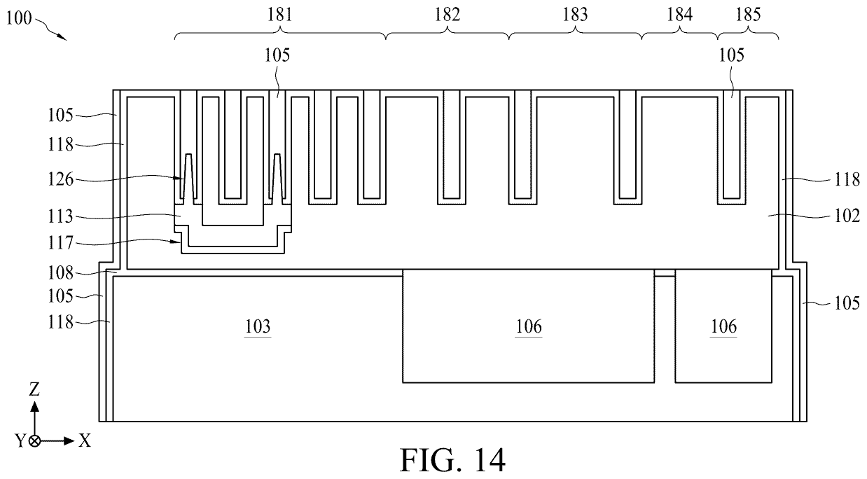

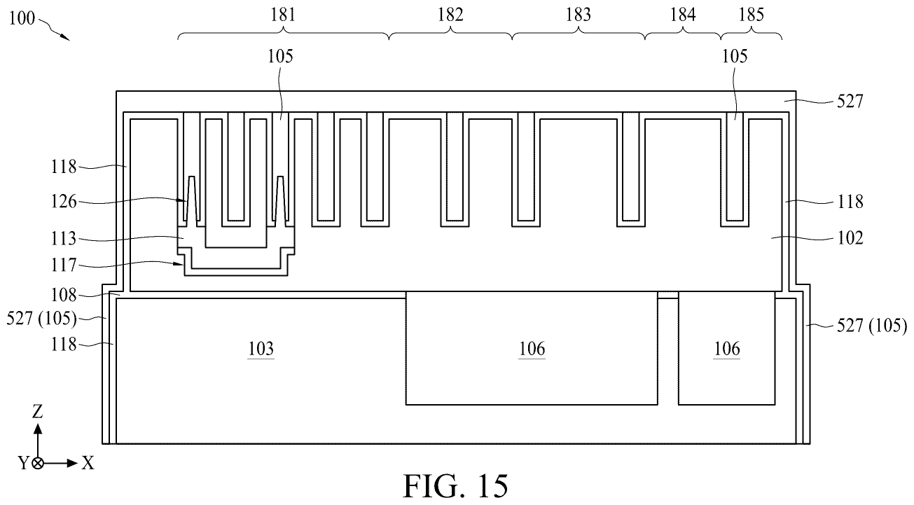

At operations 418-422, referring to FIGS. 14-16 collectively, the portions of the first silicon layer 105 formed over the top surface of the first dielectric layer 118 are further processed to obtain a more uniform top surface in the first silicon layer 105.

For example, at operation 418, referring to FIG. 14, the first silicon layer 105 is etched to remove all, or substantially all, of the portion of the first silicon layer 105 over the top surface of the first dielectric layer 118. The first silicon layer 105 may be etched using a suitable etching process as described above with respect to the operation 414 using a suitable etchant, such as carbon tetrafluoride (CF₄), hydrofluoric acid (HF), or the like. As a result, portions of the first silicon layer 105 remain over the first dielectric layer 118 within the first trench 506 and the second trench 507, and the third trenches 508 collectively. In some instances, a top surface of the etched first silicon layer 105 may include an uneven texture (e.g., having a relatively less smooth topography with microscopic cavities and/or protrusions) as a result of implementing the etching process. Thus, further processing may be needed to smooth the top surface of the first silicon layer 105.

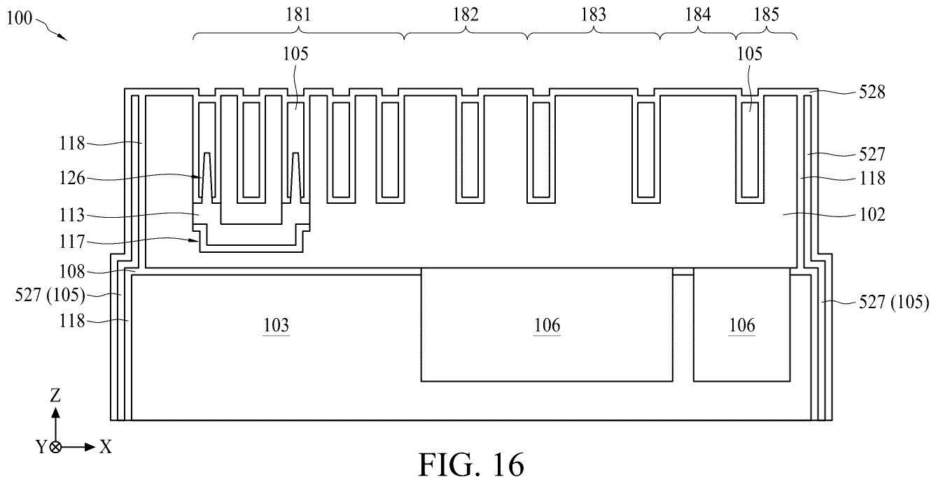

At operation 420, referring to FIG. 15, a second silicon layer 527 is formed as a blanket layer over the base structure, which includes the etched first silicon layer 105 embedded in the top wafer 102. The second silicon layer 527 has substantially the same composition as the first silicon layer 105 and may be formed in a manner similar to that of forming the first silicon layer 105 described above with respect to operation 416. In some embodiments, the second silicon layer 527 is formed to smooth the uneven texture of the top surface of the etched first silicon layer 105. For example, forming the second silicon layer 527 may fill any microscopic cavities and/or between any microscopic protrusions, thereby smoothing the uneven texture of the top surface of the etched first silicon layer 105.

At operation 422, referring to FIG. 16, portions of the second silicon layer 527 formed over the top surface 107 of the top waver 102 are removed by a suitable etching process, such as a wet etching process. Example etchants used for etching the second silicon layer 527 may include an acid, such as hydrofluoric acid (HF). In alternative embodiments, rather than etching the first silicon layer 105 at operation 418, depositing the second silicon layer 527 at operation 420, and subsequently etching the second silicon layer 527 at operation 422, the as-deposited first silicon layer 105 may be planarized or polished using a CMP process, for example, in order to achieve a smooth stop surface in the first silicon layer 105, as depicted in FIG. 16.

At operation 424, still referring to FIG. 16, a second dielectric layer 528 is formed as a conformal layer over the base structure to passivate at least the first silicon layer 105. The second dielectric layer 528 may include any suitable dielectric material, such as an oxide (e.g., silicon oxide), a nitride (e.g., silicon nitride), other suitable dielectric materials, or combinations thereof. In some embodiments, the second dielectric layer 528 has the substantially the same composition as the first dielectric layer 118. The second dielectric layer 528 may be conformally formed by any suitable process, such as CVD, PVD, ALD, thermal oxidation, chemical oxidation, other suitable processes, or combinations thereof. The resulting first silicon layer 105 (i.e., the major body 123) and the first dielectric layer 118 in each of the first trench 506 and the second trench 507 forms a corresponding one of the micromechanical arms 112 of the MEMS actuator 200. The combination of the first silicon layer 105 and the first dielectric layer 118 in each of the micromechanical arms 112 may be considered a bilayer composite structure.

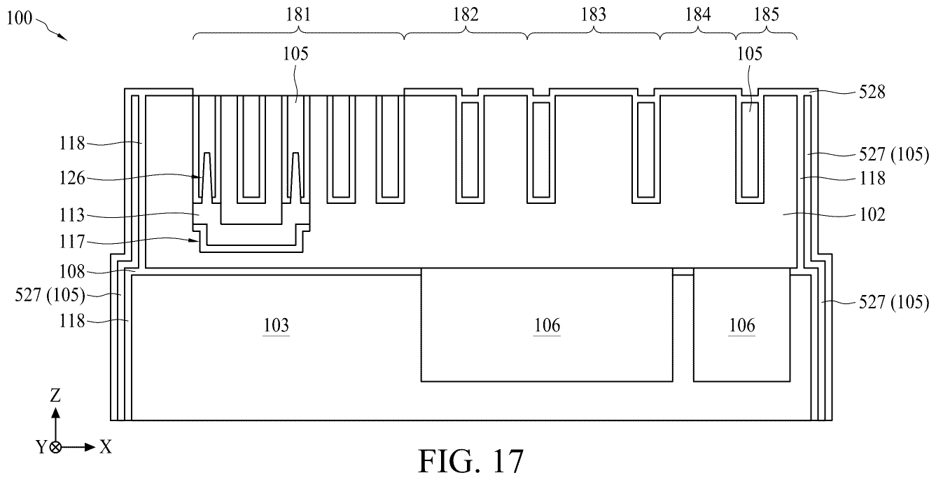

At operation 426, referring to FIG. 17, portions of the second dielectric layer 528 are removed (e.g., patterned) to expose the MEMS actuator section 181. In some embodiments, a photomask (not shown) may be formed over the top waver 102 to expose portions of the second dielectric layer 528 over the MEMS actuator section 181. Subsequently, the exposed portions of the second dielectric layer 528 are removed by a suitable etching process described above with respect to the operation 414 using a suitable etchant. After performing the etching process, portions of the second dielectric layer 528 remain over the sections (e.g., the sections 182-185) of the MEMS 100 adjacent to the MEMS actuator section 181. The photomask is subsequently removed by any suitable process, such as plasma ashing or resist stripping.

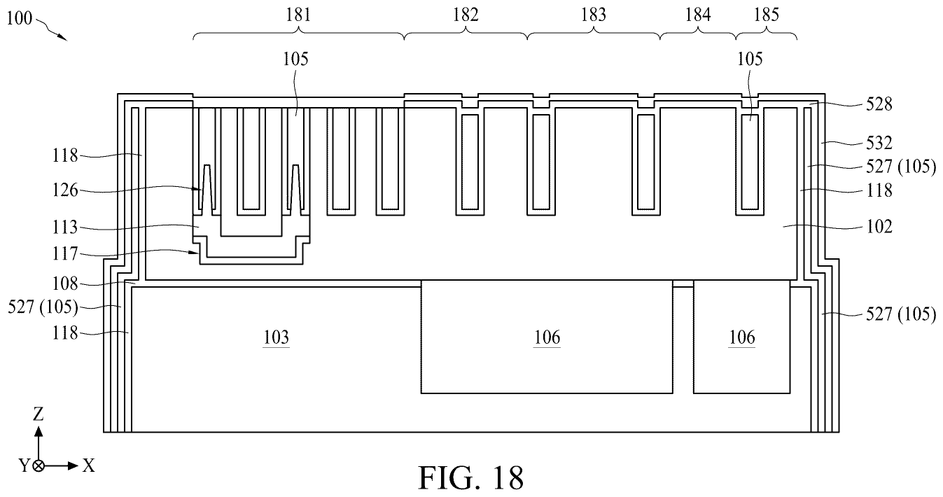

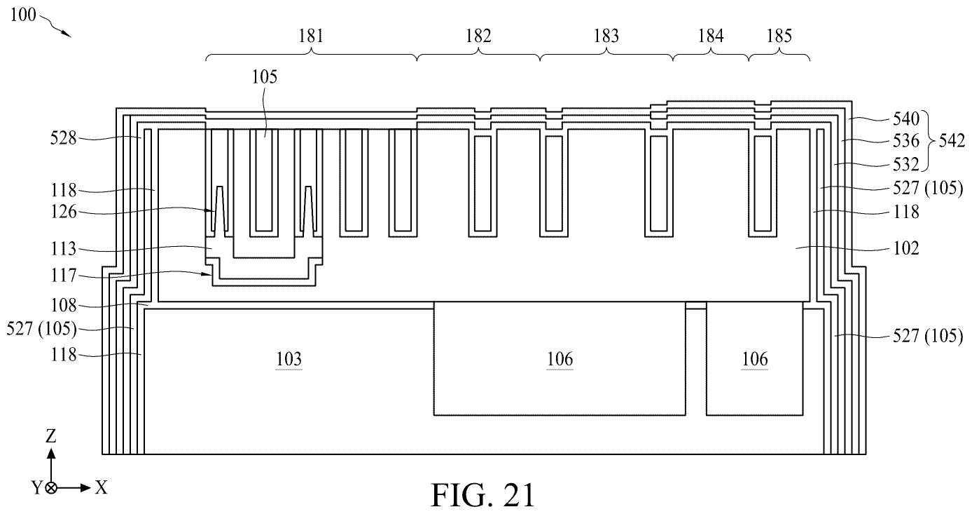

At operations 428-434, referring to FIGS. 18-21 collectively, a multilayer structure 542 (see FIG. 21) is formed over the top waver 102. The multilayer structure 542 includes a third silicon layer 532, a third dielectric layer 536 over the third silicon layer 532, and a fourth silicon layer 540 over the third dielectric layer 536. In some embodiments, the multilayer structure 542 is configured as a mask for protecting portions of the top wafer 102 against inadvertent etching of the top wafer 102 and/or the first silicon layer 105. In some embodiments, portions of the multilayer structure 542 (e.g., the third silicon layer 532 and the fourth silicon layer 540) may be sacrificially removed while performing a subsequent etching process, for example.

At operation 428, referring to FIG. 18, the third silicon layer 532 is conformally formed over the patterned second dielectric layer 528. The third silicon layer 532 may have substantially the same composition as the first silicon layer 105 and may be formed in a manner similar to that of forming the first silicon layer 105 described above with respect to operation 416.

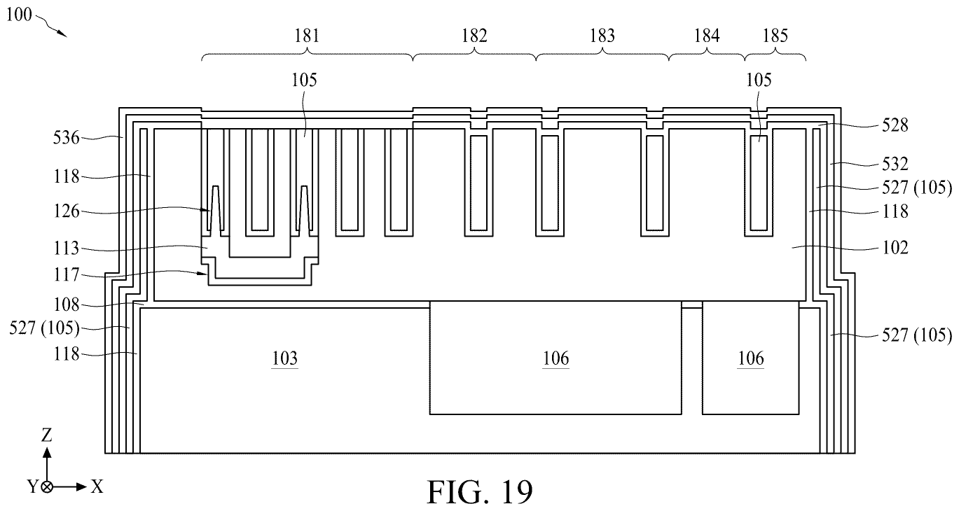

At operation 430, referring to FIG. 19, the third dielectric layer 536 is conformally formed over the third silicon layer 532. The third dielectric layer 536 may have substantially the same composition as the first dielectric layer 118 and may be formed in a manner similar to that of forming the second dielectric layer 528 described above with respect to operation 424.

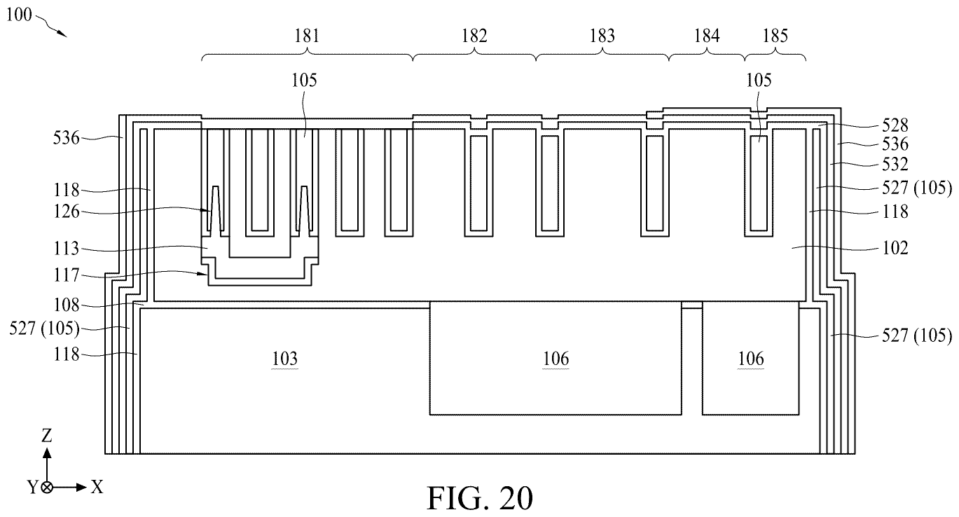

At operation 432, referring to FIG. 20, portions of the third dielectric layer 536 are removed (e.g., patterned) to expose at least a portion of the third silicon layer 532 over the MEMS actuator section 181. In some embodiments, a photomask (not shown) may be formed over the top wafer 102 to expose at least the portion of the third dielectric layer 536 over the MEMS actuator section 181. Subsequently, the exposed portions of the third dielectric layer 536 are removed by a suitable etching process described above with respect to the operation 414 using a suitable etchant. After performing the etching process, portions of the third dielectric layer 536 remain over sections (e.g., the sections 182-185) of the MEMS 100 adjacent to the MEMS actuator section 181. The photomask is subsequently removed by any suitable process, such as plasma ashing or resist stripping.

At operation 434, referring to FIG. 21, the fourth silicon layer 540 is conformally formed over the patterned third dielectric layer 536, thereby forming the multilayer structure 542. The fourth silicon layer 540 may have substantially the same composition as the third silicon layer 532 and may be formed in a manner similar to that of forming the first silicon layer 105 described above with respect to operation 416. In the present embodiments, the various silicon (e.g., polysilicon)-containing layers, including the top wafer 102 the bottom wafer 103, the third silicon layer 532, and the fourth silicon layer 540, exhibit etching selectivity against other components of the MEMS 100. In this regard, the various silicon layers can be selectively removed by a subsequently performed silicon release process.

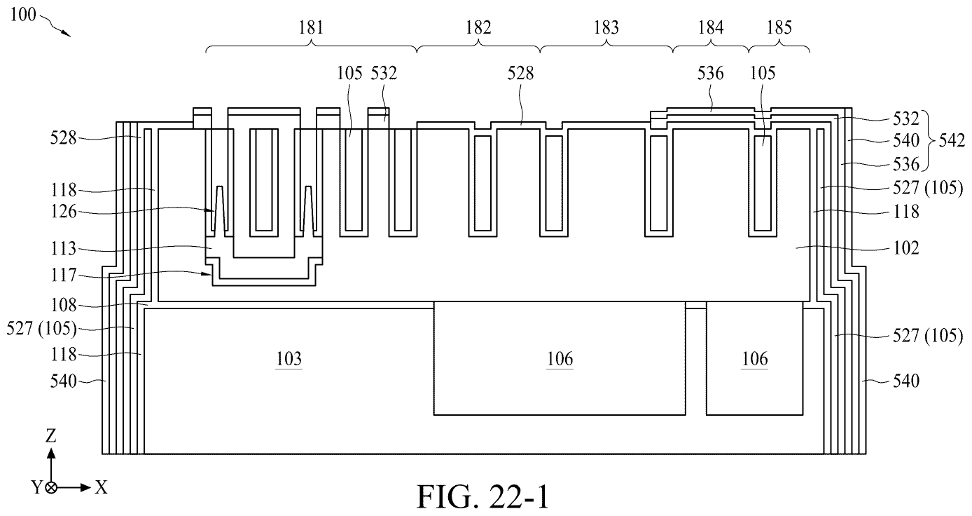

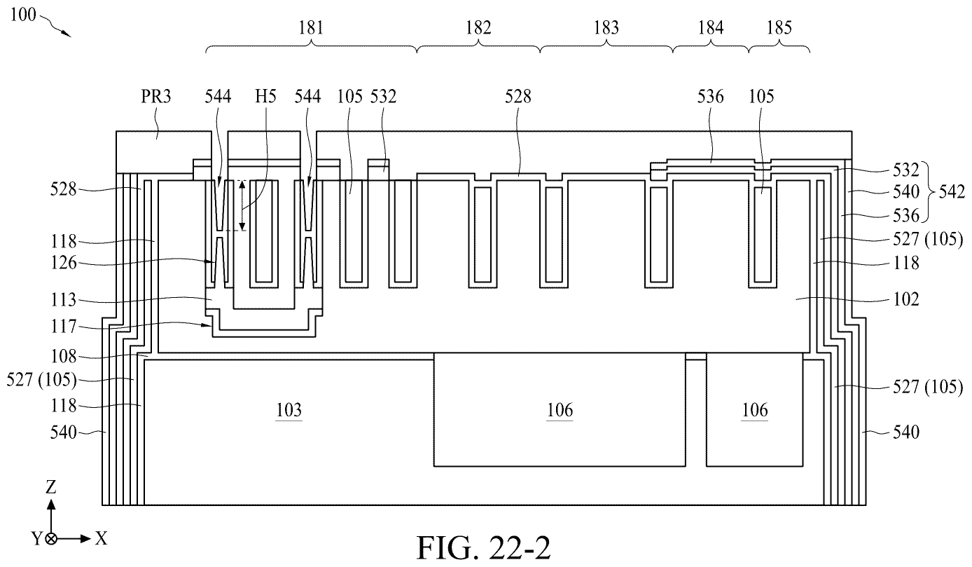

At operation 436, referring to FIG. 22-1, portions of the multilayer structure 542 are removed (e.g., patterned) to expose portions of the first silicon layer 105 included in the first micromechanical arms 112a of the MEMS actuator 200. In some embodiments, portions of the multilayer structure 542 disposed over adjacent sections of the MEMS 100 are also removed, thereby exposing portions of the second dielectric layer 528 disposed thereover.

In some embodiments, a photomask (not shown) may be formed over the top wafer 102 to expose at least the portions of the multilayer structure 542 over the first silicon layer 105 included in the first micromechanical arms 112a in the MEMS actuator section 181. In some embodiments, the photomask also exposes the portions of the multilayer structure 542 disposed over the hinge section 182 and the inner frame section 183 as shown in FIG. 22. Subsequently, the exposed portions of the multilayer structure 542 are removed by a suitable etching process described above with respect to the operation 414 using one or more suitable etchants. After performing the etching process, portions of the multilayer structure 542 remain over the second micromechanical arms 112b of the MEMS actuator 200 as well as certain sections (e.g., the spring section 184 and the outer frame section 185) of the MEMS 100 adjacent to the MEMS actuator section 181. In addition, portions of the multilayer structure 542 disposed over the hinge section 182 and the inner frame section 183 are removed at the operation 436. The photomask is subsequently removed by any suitable process, such as plasma ashing or resist stripping.

At operations 437 and 438, referring to FIGS. 22-2 and 23, the first rivet structures 120 may be optionally formed in the first silicon layer 105. In some embodiments, the operations 437 and 438 are omitted such that the method 400 proceeds from the operation 436 directly to operation 440. In this regard, the first rivet structures 120 are omitted from the MEMS 100, such as the embodiment depicted in FIG. 2A.

At operation 437, referring to FIG. 22-2, potions of the first silicon layer 105 exposed by the patterned multilayer structure 542 are removed. As depicted herein, a patterned photomask PR3 is formed over portions of the patterned multilayer structure 542, where the patterned photomask PR3 includes openings that correspond to positions of the first rivet structures 120 to be formed in the first silicon layer 105. Subsequently, the portions of the first silicon layer 105 exposed in the openings are removed by a suitable etching process similar to that described above with respect to the operation 418, resulting in fourth trenches 544.

Still referring to FIG. 22-2, the fourth trenches 544 extend partially through the first silicon layer 105 along the vertical direction. In some embodiments, parameters of the etching process are adjusted to control a geometry and a depth H5 of the fourth trenches 544, which correspond to a geometry of the resulting first rivet structures 120. For a dry etching process or an RIE process, the parameters of the etching process may include, for example, a duration of the etching process, a voltage applied during the etching process, or the like. In one example, the parameters of the etching process may be controlled such that the geometry of the fourth trenches 544 is substantially the same as a geometry of the second rivet structure 126, as depicted in the embodiments of FIGS. 2B and 2C. In another example, the parameters of the etching process may be controlled such that the geometry of the fourth trenches 544 is different from (e.g., asymmetric to) a geometry of the second rivet structure 126, as depicted in the embodiment of FIG. 2D.

Furthermore, the etching parameters may be adjusted such that the depth H5 of the fourth trenches 544 is shallow enough so as to only expose a portion of the first silicon layer 105 but not the second rivet structures 126. In this regard, the subsequently formed first rivet structures 120 are physically separated from the corresponding second rivet structures 126 along the vertical direction, as depicted in the embodiment of FIG. 2B. Alternatively, as depicted in FIG. 2C, the etching parameters may be adjusted such that the depth H5 of the fourth trenches 544 is large enough so as to expose the second rivet structures 126. In this regard, the subsequently formed first rivet structures 120 are physically coupled to the corresponding second rivet structures 126 along the vertical direction, as depicted in FIGS. 2C and 2D.

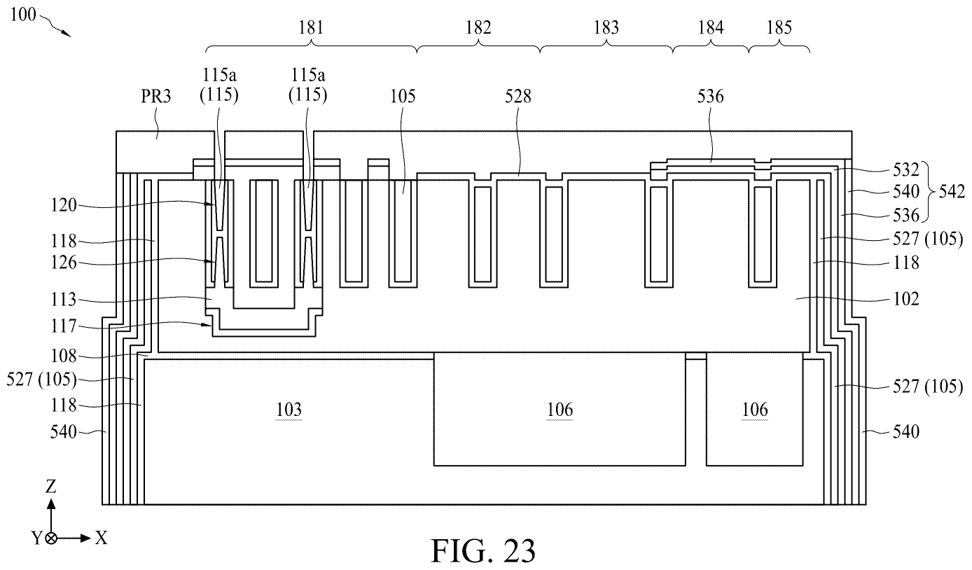

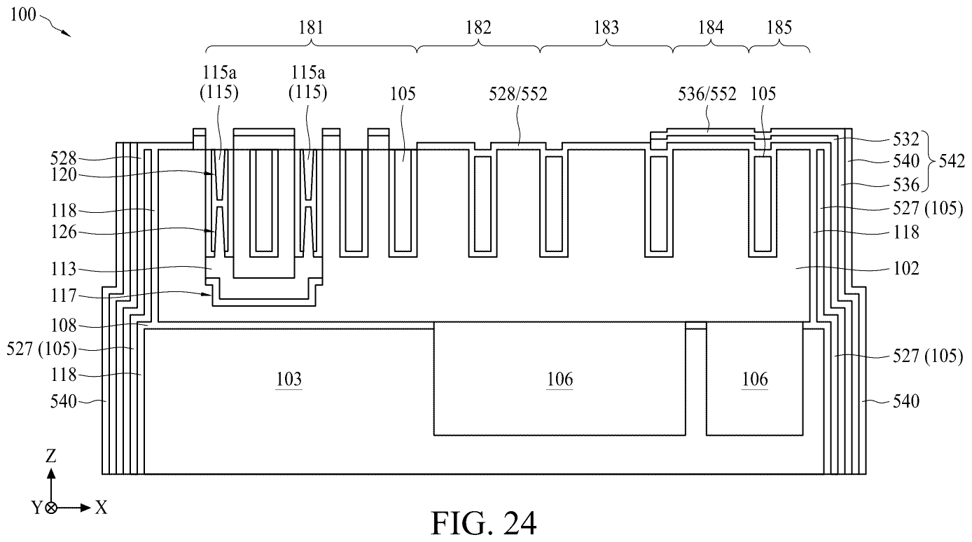

At operation 438, referring to FIG. 23, the second metal layer 115 is deposited over the top wafer 102 such that a first portion 115a of the second metal layer 115 fills the fourth trenches 544 and forms the first rivet structures 120. The second metal layer 115 may have substantially the same composition as the first metal layer 113 and may be deposited in a manner similar to that of depositing the first metal layer 113 described above with respect to operation 412. In some embodiments, the patterned photomask PR3 is used as a deposition mask when depositing the second metal layer 115. Thereafter, portions of the second metal layer 115 may be removed by a dry etching process, for example, using the patterned photomask PR3 as an etch mask, such that the resulting the first portion 115a (i.e., the first rivet structures 120) have a top surface substantially planar with the first silicon layer 105 in the adjacent second micromechanical arm 112b. After etching the second metal layer 115, the patterned photomask PR3 is removed from the MEMS 100 by a suitable method, such as plasma ashing or resist stripping, resulting in the structure depicted in FIG. 24.

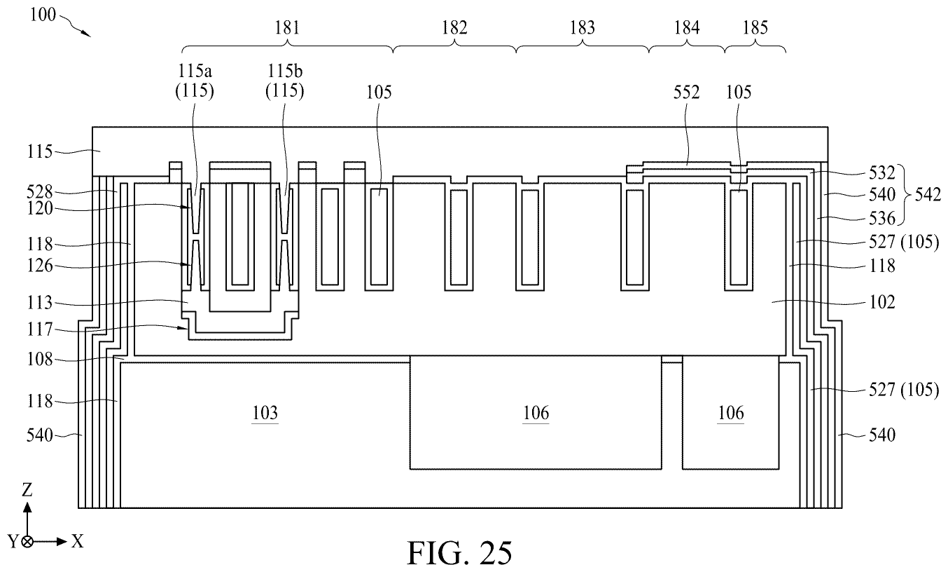

At operation 440, referring to FIG. 25, the second metal layer 115 is deposited over the patterned multilayer structure 542 such that a second portion 115b of the second metal layer 115 is formed over the micromechanical arms 112. The second metal layer 115 may be deposited in a manner similar to that of depositing the first metal layer 113 described above with respect to operation 412. Portions of the second metal layer 115 fill openings in the patterned multilayer structure 542, resulting in the top proximal portions 116a over the first micromechanical arms 112a and physically coupled to or contiguous with the corresponding rivet structure 120 (if present).

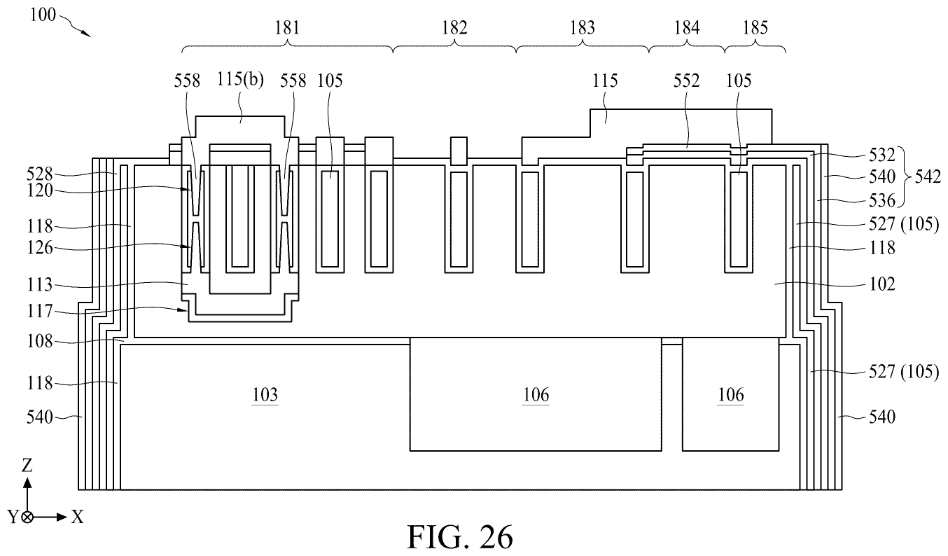

At operation 442, referring to FIG. 26, portions of the second metal layer 115 are removed (e.g., patterned) to form the second portion 115b over the first silicon layer 105 and the first portion 115a (if present). In some embodiments, a photomask (not shown) may be formed over the top wafer 102 to expose at least the portions of the second metal layer 115. In some embodiments, the photomask also exposes the portions of the first dielectric layer 118 and/or the second dielectric layer 528 adjacent to the first silicon layer 105. Subsequently, the exposed portions of the second metal layer 115 are removed by a suitable etching process described above with respect to the operation 414. After performing the etching process, the second portion 115b of the second metal layer 115 remains over the micromechanical arms 112 to complete formation of the top capping member 116.

As described above, the resulting top capping member 116 is disposed over and coupled to the first micromechanical arms 112a. For embodiments in which the operations 437 and 438 are implemented (i.e., the first portion 115a of the second metal layer 115 is formed in the first silicon layer 105), the second portion 115b is physically coupled to the first portion 115a (i.e., the first rivet structures 120) to form the top capping member 116. For embodiments in which the operations 437 and 438 are omitted (i.e., the first portion 115a of the second metal layer 115 is not formed in the first silicon layer 105), the second portion 115b of the second metal layer 115 is physically coupled to the top portion of the first silicon layer 105 to form the top capping member 116.

In some embodiments, after performing the patterning process at operation 446, portions of the second metal layer 115 also remain over the first silicon layer 105 formed in other sections of the MEMS 100 adjacent to the MEMS actuator section 181. Thereafter, the photomask is subsequently removed by any suitable process, such as plasma ashing or resist stripping.

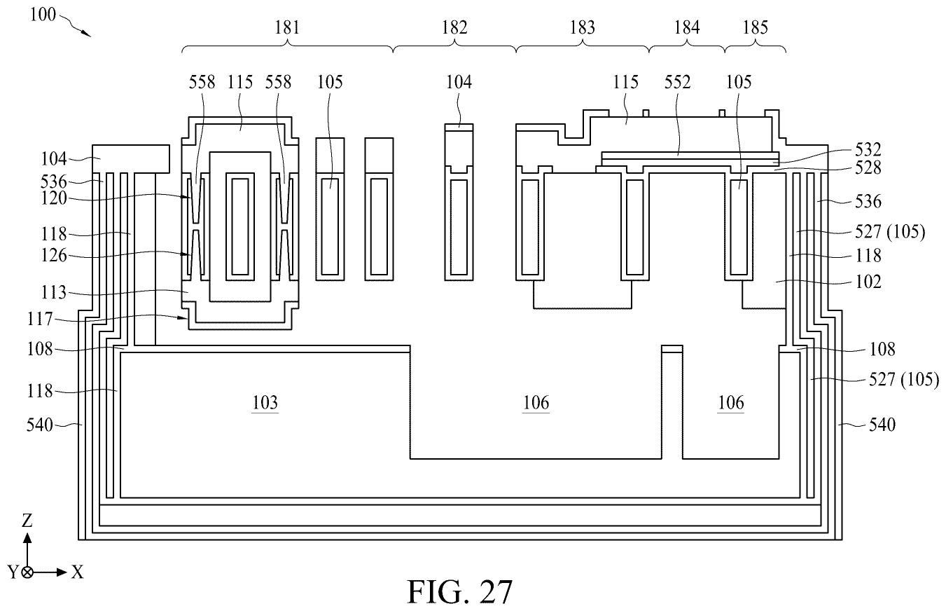

At operation 444, referring to FIG. 27, the passivation layer 104 is deposited over the patterned second metal layer 115. The passivation layer 104 includes a dielectric material that acts as a protective barrier, providing insulation and protection against moisture and contaminants that affect the MEMS 100. In some embodiments, the passivation layer 104 includes silicon oxide (SiO₂), silicon nitride (Si₃N₄), silicon oxynitride (SiON), aluminum oxide (Al₂O₃), titanium nitride (TiN), other suitable dielectric materials, or combinations thereof. In the present embodiments, the passivation layer 104 exhibits etching selectivity against the silicon (e.g., polysilicon)-containing components (e.g., the top wafer 102, the bottom wafer 103, the third silicon layer 532, and the fourth silicon layer 540). The passivation layer 104 may be formed by any suitable methods, such as CVD, low-pressure CVD (LPCVD), plasma-enhanced CVD (PECVD), PVD, ALD, other suitable methods, or combinations thereof.

At operation 446, still referring to FIG. 27, portions of the top wafer 102 and the patterned multilayer structure 542 are removed, resulting in the MEMS 100 as depicted in at least FIG. 1. As the top wafer 102 and portions of the multilayer structure 542 (i.e., the third silicon layer 532 and the fourth silicon layer 540) include silicon (e.g., polysilicon), a silicon release process may be performed at the operation 448 to form the continuous cavity 106 as depicted in FIG. 1, for example. The silicon release process may also be referred to as a “sacrificial release process” and may include any suitable etching process described above with respect to the operation 418. In one example, the silicon release process may include a dry etching process implemented using an etchant such as carbon tetrafluoride (CF₄). In another example, the silicon release process may include a wet etching process implemented using an etchant such as hydrofluoric acid (HF). The silicon release process can be additionally or alternatively implemented using other suitable etchants and/or etching processes.

In various embodiments, the etching process selectively removes silicon at a higher rate than other components, such as metals (e.g., the first metal layer 113 and the second metal layer 115) and dielectric materials (e.g., the first dielectric layer 118 and the passivation layer 104), of the MEMS 100. In this regard, the first dielectric layer 118 can serve as an etch-stop layer to protect the underlying first silicon layer 105 in the micromechanical arms 112, which is not etched, or substantially etched, by the silicon release process.

FIG. 28 is a diagram illustrating a sensor-shift OIS system 600 in accordance with some embodiments of the present disclosure. The sensor-shift OIS system 600 includes, among other components, a MEMS such as the MEMS 100 described herein, an image sensor 602, and a lens 604. The image sensor 602 is attached to the MEMS 100 and is operable to detect and convey information used to make an image. The image sensor 602 converts the variable attenuation of light waves coming through the lens 604 into signals. In some embodiments, the image sensor 602 includes a charge-coupled device (CCD). In some embodiments, the image sensor 602 includes a complementary metal oxide semiconductor (CMOS) image sensor. A CMOS image sensor typically includes a micro-lens that gathers light, color filters that separate out the red, green, and blue (RGB) components, and a photodiode that captures the filtered light. In some examples, the CMOS image sensor is a front-side illumination (FSI) CMOS image sensor. In some examples, the CMOS image sensor is a backside illumination (BSI) CMOS image sensor.

As described above, the MEMS 100 may include, for example, four MEMS actuators 200a, 200b, 200c, and 200d (collectively referred to as the MEMS actuators 200 as described herein), each of which may move in one direction, and the movement is controlled by electrical signals. As a result, the image sensor 602 attached to the MEMS 100 can be moved accordingly under the control of electrical signals, thus achieving sensor-shift OIS.

In accordance with one aspect of the present disclosure, an actuator of a MEMS includes a semiconductor substrate. The actuator includes an array of micromechanical arms disposed over the semiconductor substrate. The actuator includes a first capping member disposed over the micromechanical arms. The actuator includes a second capping member disposed opposite the first capping member such that the micromechanical arms extend between the first capping member and the second capping member along a vertical direction.

In accordance with another aspect of the present disclosure, an actuator of a MEMS includes a semiconductor substrate. The actuator includes first micromechanical arms and second micromechanical arms disposed over the semiconductor substrate. The first micromechanical arms and the second micromechanical arms are separated from and interleaved with one another along a first direction. The actuator includes a top capping member coupled to the first micromechanical arms. The actuator includes a bottom capping member also coupled to the first micromechanical arms such that the first micromechanical arms and the second micromechanical arms extend between the top capping member and the bottom capping member along a second direction perpendicular to the first direction.

In accordance with yet another aspect of the present disclosure, a method of forming an actuator of the MEMS includes forming a first trench and a second trench in an actuator section of a substrate. The first trench includes a horizontal portion coupled to two vertical portions. The second trench is surrounded by the first trench. The method includes forming a first dielectric layer in the first trench and the second trench. The method includes depositing a first metal layer over the first dielectric layer. The method includes etching the first metal layer, resulting in a bottom capping member in a bottom portion of the first trench. The method includes forming a semiconductor layer over the first metal layer to fill the first trench and the second trench. The method includes planarizing the semiconductor layer, thereby forming first micromechanical arms and second micromechanical arms in the first trench and the second trench, respectively. The method includes forming a patterned second dielectric layer over the semiconductor layer, exposing the first micromechanical arms and the second micromechanical arms. The method includes forming a multilayer structure overlaying the first micromechanical arms and the second micromechanical arms. The method includes patterning the multilayer structure to expose the first micromechanical arms in third trenches without exposing the second micromechanical arms. The method includes depositing a second metal layer over the patterned multilayer structure, thereby filling the third trenches. The method includes patterning the second metal layer to form a top capping member over the first micromechanical arms and the second micromechanical arms, thereby forming an actuator in the actuator section. The method includes forming a second dielectric layer over the top capping member. The method includes removing portions of the multilayer structure and the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An actuator of a micro-electromechanical system (MEMS), comprising:
a semiconductor substrate;
micromechanical arms disposed over the semiconductor substrate;
a first capping member disposed over the micromechanical arms; and
a second capping member disposed opposite the first capping member such that the micromechanical arms extend between the first capping member and the second capping member along a vertical direction.

2. The actuator of claim 1, wherein:
the first capping member includes a first portion protruding into a first array of the micromechanical arms,
the second capping member includes a second portion protruding into the first array of the micromechanical arms, and
the first portion and the second portion extending towards one another along the vertical direction.

3. The actuator of claim 2, wherein the first portion and the second portion are physically coupled to one another along the vertical direction.

4. The actuator of claim 2, wherein the first portion and the second portion are physically separated from one another.

5. The actuator of claim 2, wherein the first portion has a first width along a horizontal direction perpendicular to the vertical direction and the second portion has a second width along the horizontal direction, wherein the first width decreases from the first capping member towards the second capping member, and wherein the second width decreases from the second capping member towards the first capping member.

6. The actuator of claim 1, wherein the micromechanical arms include a semiconductor material, and wherein each of the first capping member and the second capping member includes a conductive material.

7. The actuator of claim 1, wherein each of the first capping member and the second capping member includes a proximal portion coupled to a distal portion, and wherein the proximal portion is further coupled to a first array of the micromechanical arms.

8. The actuator of claim 7, wherein the micromechanical arms further include a second array spaced from and interleaved with the first array along a horizontal direction perpendicular to the vertical direction, and wherein the second array is not coupled to the first capping member and the second capping member in a cross-sectional view of the MEMS.

9. An actuator of a micro-electromechanical system (MEMS), comprising:
a semiconductor substrate;
first micromechanical arms and second micromechanical arms disposed over the semiconductor substrate, the first micromechanical arms and the second micromechanical arms separated from and interleaved with one another along a first direction;
a top capping member coupled to the first micromechanical arms; and
a bottom capping member also coupled to the first micromechanical arms such that the first micromechanical arms and the second micromechanical arms extend between the top capping member and the bottom capping member along a second direction perpendicular to the first direction.

10. The actuator of claim 9, wherein the second micromechanical arms are free of contact with the top capping member and the bottom capping member.

11. The actuator of claim 9, wherein:
the top capping member includes a first portion protruding into a top portion of each of the first micromechanical arms,
the bottom capping member includes a second portion protruding into a bottom portion of each of the first micromechanical arms, and
the first portion and the second portion extending towards one another along the second direction.

12. The actuator of claim 11, wherein the first portion and the second portion meet at an interface, wherein the first portion has a first width along the interface and the second portion has a second width along the interface, and wherein the first width differs from the second width.

13. The actuator of claim 11, wherein the first portion and the second portion meet at an interface, wherein the first portion has a first width along the interface and the second portion has a second width along the interface, and wherein the first width is is equal to the second width.

14. The actuator of claim 11, wherein the first portion and the second portion are free of contact with one another.

15. The actuator of claim 9, wherein each of the first micromechanical arms and the second micromechanical arms includes an oxide layer surrounding a metal layer.

16. The actuator of claim 9, further comprising a passivation layer extending along a top surface of the top capping member and along a bottom surface of the bottom capping member.

17. A method of forming an actuator of a micro-electromechanical system (MEMS), comprising:
forming a first trench and a second trench in a substrate, the first trench including a horizontal portion coupled to two vertical portions, and the second trench surrounded by the first trench;
forming a first dielectric layer in the first trench and the second trench;
depositing a first metal layer over the first dielectric layer;
etching the first metal layer, resulting in a bottom capping member in a bottom portion of the first trench;
forming a semiconductor layer over the first metal layer to fill the first trench and the second trench;
planarizing the semiconductor layer, thereby forming first micromechanical arms and second micromechanical arms in the first trench and the second trench, respectively;
forming a patterned second dielectric layer over the semiconductor layer, exposing the first micromechanical arms and the second micromechanical arms;
forming a multilayer structure overlaying the first micromechanical arms and the second micromechanical arms;
patterning the multilayer structure to expose the first micromechanical arms in third trenches without exposing the second micromechanical arms;
depositing a second metal layer over the patterned multilayer structure, thereby filling the third trenches;
patterning the second metal layer to form a top capping member over the first micromechanical arms and the second micromechanical arms, thereby forming the actuator;
forming a second dielectric layer over the top capping member; and
removing portions of the multilayer structure and the substrate.

18. The method of claim 17, wherein etching the first metal layer causes portions of the first metal layer to protrude vertically from the substrate.

19. The method of claim 17, further comprising, before depositing the second metal layer, etching the exposed first micromechanical arms to form cavities in the semiconductor layer such that depositing the second metal layer causes portions of the second metal layer to protrude vertically towards the substrate.

20. The method of claim 17, wherein the top capping member and the bottom capping member are formed to directly contact one another.
